(19) United States
(12) Patent Application Publication
(10) Pub. No.: US 2026/0096339 A1
(43) Pub. Date: Apr. 2, 2026

(54) DISPLAY DEVICE AND ELECTRONIC DEVICE

(71) Applicant: Sony Group Corporation, Tokyo (JP)

(72) Inventors: Hiroaki TOYOSHIMA, Tokyo (JP); Yasutake FURUKOSHI, Kanagawa (JP)

(73) Assignee: Sony Group Corporation, Tokyo (JP)

(21) Appl. No.: 19/112,964

(22) PCT Filed: Oct. 4, 2023
(86) PCT No.: PCT/JP2023/036150

§ 371 Date: Mar. 19, 2025

(30) Foreign Application Priority Data
Oct. 12, 2022 (JP) 2022-164280

(51) Int. Cl. H10K 85/20; H10K 50/13; H10K 50/15; H10K 50/16; H10K 50/17; H10K 50/18; H10K 50/19

(52) U.S. Cl. CPC H10K 85/20; H10K 50/13; H10K 50/15; H10K 50/16; H10K 50/17; H10K 50/181; H10K 50/19

(57) ABSTRACT

A display device that includes a display panel that has a plurality of organic EL elements, and a drive unit that is provided to be in contact with the display panel and drives the display panel, in which each organic EL element includes an organic layer that contains a high glass transition temperature material having a glass transition point of 120° C. or higher, is provided.

### FIELD

The present disclosure relates to a display device and an electronic device.

### BACKGROUND

In recent years, a display panel (display device) including an organic electro-luminescence (EL) element called an organic light emitting diode (OLED) or the like has been rapidly made thinner and lighter. Furthermore, there has been proposed a display panel in which an actuator, a diaphragm, or the like is installed on the back surface of such a display panel, and the panel itself is vibrated to play a sound.

### CITATION LIST

### Patent Literature

Patent Literature 1: JP 2022-62222 A

### SUMMARY

### Technical Problem

However, in the display panel (display device) in which the panel itself is vibrated to play a sound, color unevenness may occur in displayed images.

Therefore, the present disclosure proposes a display device and an electronic device capable of reducing the occurrence of color unevenness in displayed images.

### Solution to Problem

According to the present disclosure, there is provided a display device including: a display panel that has a plurality of organic EL elements; and a drive unit that is provided to be in contact with the display panel and drives the display panel. In the display device, each organic EL element includes an organic layer that contains a high glass transition temperature material having a glass transition point of 120° C. or higher.

Furthermore, according to the present disclosure, there is provided an electronic device including a display device. In the electronic device, the display device includes: a display panel that has a plurality of organic EL elements, and a drive unit that is provided to be in contact with the display panel and drives the display panel, and each organic EL element includes an organic layer that contains a high glass transition temperature material having a glass transition point of 120° C. or higher.

### BRIEF DESCRIPTION OF DRAWINGS

FIG. 1 is a perspective diagram illustrating a schematic configuration example of a display 1 of the present disclosure.

FIG. 2 is a circuit diagram of a circuit configuration example of the display 1 of the present disclosure.

FIG. 3 is a circuit diagram of a circuit configuration example of a pixel 11 of the display 1 of the present disclosure.

FIG. 4 is a diagram illustrating an exploded perspective configuration example of a display panel 10 of the present disclosure.

FIG. 5 is a diagram illustrating a functional block example of a system circuit board 40 of the present disclosure.

FIG. 6 is an explanatory diagram (part 1) for explaining the background of embodiments of the present disclosure.

FIG. 7 is an explanatory diagram (part 2) for explaining the background of the embodiments of the present disclosure.

FIG. 8 is a diagram illustrating a configuration example of an organic EL element of a first embodiment of the present disclosure.

FIG. 9 is a diagram illustrating a configuration example of an organic EL element of a second embodiment of the present disclosure.

FIG. 10 is a diagram illustrating a configuration example of an organic EL element of a third embodiment of the present disclosure.

FIG. 11 is a diagram illustrating a configuration example of an organic EL element of a fourth embodiment of the present disclosure.

FIG. 12 is a diagram (part 1) illustrating a configuration example of an organic EL element of a fifth embodiment of the present disclosure.

FIG. 13 is a diagram (part 2) illustrating a configuration example of the organic EL element of the fifth embodiment of the present disclosure.

### DESCRIPTION OF EMBODIMENTS

Hereinafter, suitable embodiments of the present disclosure will be described in detail with reference to the accompanying drawings. Note that, in the present specification and the drawings, components having substantially the same functional configuration are denoted by the same reference numerals, and redundant descriptions will be omitted. In addition, in the present specification and the drawings, a plurality of components having substantially the same or similar functional configuration may be denoted and distinguished by different alphabets after the same reference numeral. However, in a case where there is no need to particularly distinguish each of the plurality of components having substantially the same or similar functional configuration, only the same reference numeral is attached.

Note that the description will be given in the following order.
1. Background Leading to Creation of Embodiments of Present Disclosure
1.1 Schematic Configuration of Display
1.2 Background
2. Summary of Embodiments of Present Disclosure
3. First Embodiment
4. Second Embodiment
5. Third Embodiment
6. Fourth Embodiment
7. Fifth Embodiment
8. Sixth Embodiment
9. Conclusion
10. Endnotes

### 1. BACKGROUND LEADING TO CREATION OF EMBODIMENTS OF PRESENT DISCLOSURE

### 1.1 Schematic Configuration of Display

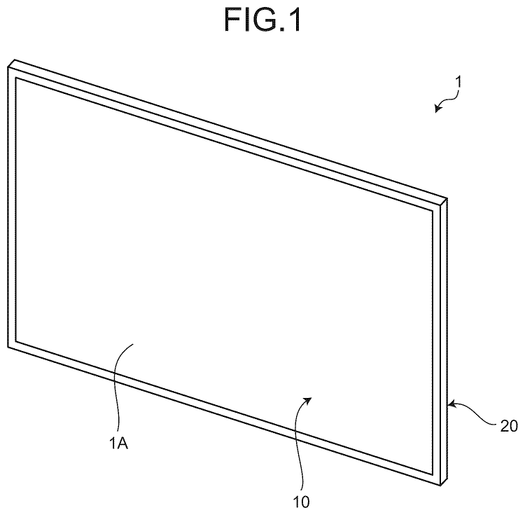

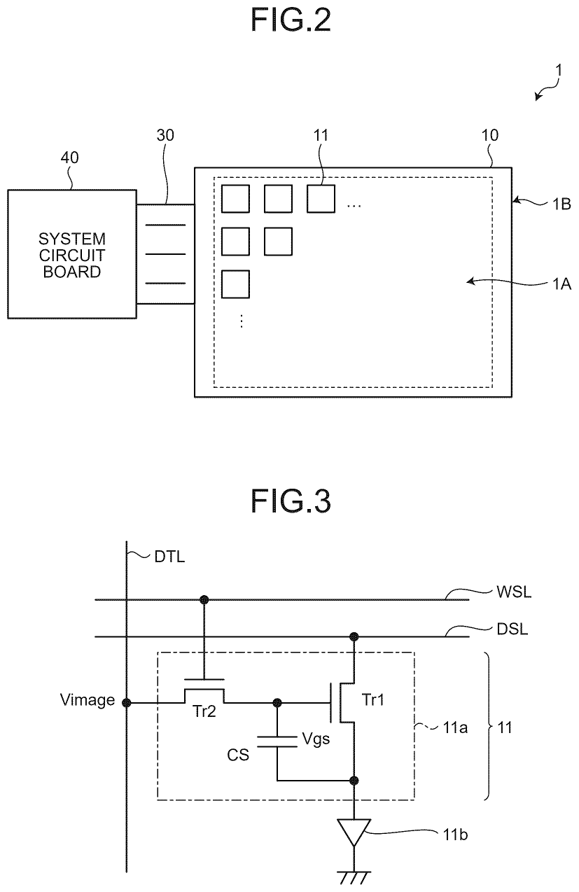

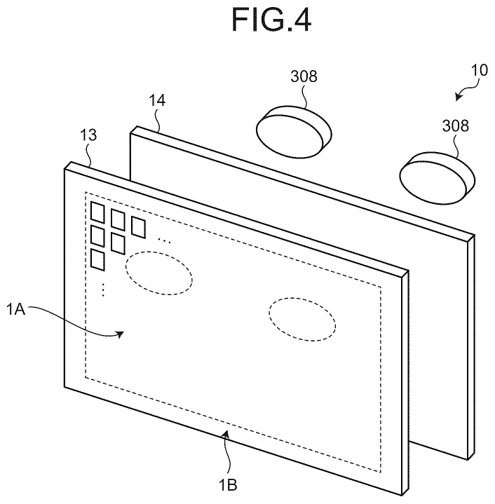

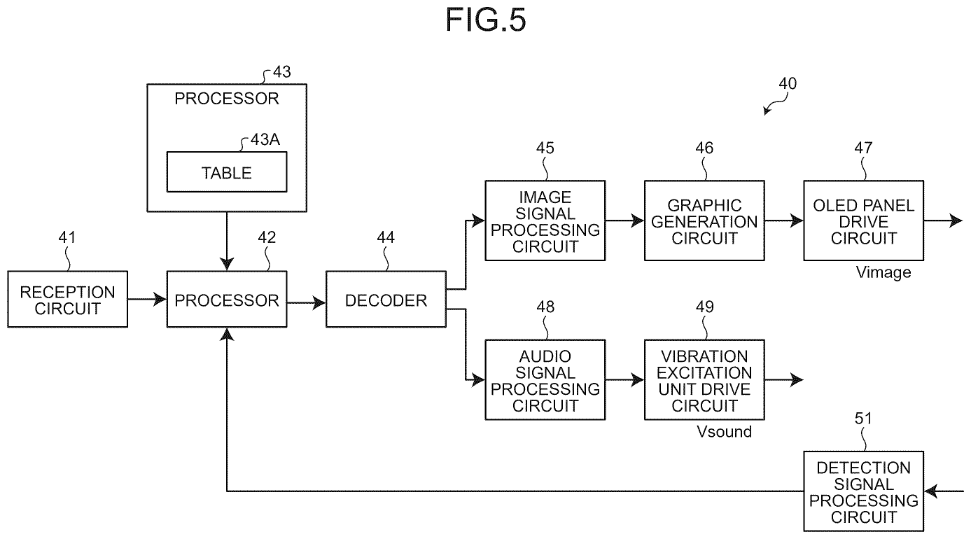

First, before describing embodiments of the present disclosure, a schematic configuration of a display (display device) 1 will be described with reference to FIGS. 1 to 5 as the background leading the present inventors to create the embodiments of the present disclosure. FIG. 1 is a perspective diagram illustrating a schematic configuration example of the display 1 of the present disclosure, FIG. 2 is a circuit diagram of a circuit configuration example of the display 1 of the present disclosure, and FIG. 3 is a circuit diagram of a circuit configuration example of a pixel 11 of the display 1 of the present disclosure. FIG. 4 is a diagram illustrating an exploded perspective configuration example of a display panel 10 of the present disclosure, and FIG. 5 is a diagram illustrating a functional block example of a system circuit board 40 of the present disclosure. Note that the display 1 corresponds to a specific example of a “display device” of the present disclosure.

The display 1 is a self-emissive thin display with an organic electro-luminescence (EL) element called an organic light emitting diode (OLED) or the like, as a pixel.

The display 1 includes, for example, a display panel 10 that has a display region 1A, and a frame 20 that protects edges of the display panel 10 (peripheral edges of the display region 1A). Furthermore, as illustrated in FIG. 2, the display 1 includes, for example, a system circuit board 40 that drives the display panel 10, and a printed circuit 30 that electrically connects the display panel 10 and the system circuit board 40. In addition, a plurality of pixels 11 are arranged in a matrix in the display region 1A of the display panel 10. Note that, in the present disclosure, the system circuit board 40 is provided on the back surface side of the display panel 10, but in FIG. 2, for convenience, the system circuit board 40 is illustrated beside the display panel 10.

FIG. 3 illustrates a circuit diagram of a circuit configuration example of a pixel 11 of the display 1 of the present disclosure. The display panel 10 includes, for example, a plurality of gate lines WSL and a plurality of power supply lines DSL, which extend in the row direction, and a plurality of data lines DTL, which extends in the column direction. A pixel 11 is provided corresponding to an intersection between a data line DTL and a gate line WSL. Each data line DTL, each gate line WSL, and each power supply line DSL are electrically connected to an output end of the system circuit board 40 via the printed circuit 30.

The scanning line WSL is used to select each pixel 11, and supplies a selection pulse for selecting each pixel 11 for each predetermined unit (for example, pixel row) to each pixel 11. The signal line DTL is used to supply a signal voltage (signal voltage Vimage described later) corresponding to an image signal to each pixel 11, and supplies a data pulse including the signal voltage Vimage to each pixel 11. The power supply line DSL supplies power to each pixel 11.

Each pixel 11 includes, for example, a pixel that emits red light, a pixel that emits green light, or a pixel that emits blue light. Note that each pixel 11 may be, for example, a pixel that further emits light of another color (for example, white light, yellow light, or the like). The plurality of signal lines DTL is allocated one by one for each pixel column, for example. The plurality of scanning lines WSL is allocated one by one for each pixel row, for example. The plurality of power supply lines DSL is allocated one by one for each pixel row, for example.

Each pixel 11 includes a pixel circuit 11a and an organic EL element 11b. The pixel circuit 11a controls light emission and extinction of the organic EL element 11b. The pixel circuit 11a has a function of holding a voltage (signal voltage Vimage) written in each pixel 11 by signal writing described later. The pixel circuit 11a further has a function of outputting a drive current having a magnitude corresponding to the magnitude of the held voltage to the organic EL element 11b. The pixel circuit 11a includes, for example, a drive transistor Tr1, a write transistor Tr2, and a storage capacitor Cs.

The write transistor Tr2 controls the application of the signal voltage Vimage corresponding to the image signal to the gate of the drive transistor Tr1. Specifically, the write transistor Tr2 samples a voltage of the signal line DTL and writes the voltage obtained by the sampling to the gate of the drive transistor Tr1. Writing of the voltage obtained by the sampling to the gate of the drive transistor Tr1 is referred to as signal writing. The drive transistor Tr1 is connected in series to the organic EL element 11b. The drive transistor Tr1 drives the organic EL element 11b. The drive transistor Tr1 controls the current flowing through the organic EL element 11b according to the magnitude of the voltage sampled by the write transistor Tr2. The storage capacitor Cs can store a predetermined voltage between the gate and source of the drive transistor Tr1. The storage capacitor Cs functions to store a voltage Vgs between the gate and source of the drive transistor Tr1 to be constant during a predetermined period. Note that the pixel circuit 11a may have a circuit configuration in which various capacitors and transistors are added to a 2Tr-1C circuit, or may have a circuit configuration different from the configuration of the 2Tr-1C circuit.

A gate of the write transistor Tr2 is connected to the scanning line WSL. A source or a drain of the write transistor Tr2 is connected to the signal line DTL. The terminal of the write transistor Tr2, either the source or the drain, that is not connected to the signal line DTL is connected to the gate of the drive transistor Tr1. A source or a drain of the drive transistor Tr1 is connected to the power supply line DSL. The terminal of the drive transistor Tr1, either the source or the drain, that is not connected to the power supply line DSL is connected to the anode of the organic EL element 11b. One end of the storage capacitor Cs is connected to the gate of the drive transistor Tr1. The other end of the storage capacitor Cs is connected to the terminal on the organic EL element 11b side out of the source or the drain of the drive transistor Tr1.

FIG. 4 illustrates an exploded perspective configuration example of the display panel 10 of the present disclosure. The display panel 10 includes, for example, a panel 13, a heat dissipation film 14 disposed on the back surface side of the panel 13, and vibration excitation units 308. These panel 13 and heat dissipation film 14 are laminated with an adhesive interposed therebetween, for example. The vibration excitation units 308 are provided to be in contact with the panel 13 through the heat dissipation film 14. Note that, in the present disclosure, the heat dissipation film 14 may not be provided. In this case, the vibration excitation units 308 are provided to be in contact with the panel 13.

The panel 13 is a panel provided with a frame region 1B that includes the display region 1A in which the plurality of pixels 11 is disposed in a matrix on a substrate. For example, a vibration excitation unit drive circuit 49 (see FIG. 5) described later vibrates the vibration excitation unit (vibration exciter) 308 based on a signal voltage (signal voltage Vsound described later) corresponding to an audio signal, and transmits the vibration to the panel 13. Accordingly, the panel 13 can function as a planar speaker. In addition, in the present disclosure, for example, one or more vibration excitation units 308 including an actuator may be provided on the back surface side of the panel 13. In addition, the heat dissipation film 14 dissipates the heat generated in the panel 13 by the vibration excitation units 308 to the outside.

FIG. 5 illustrates a functional block example of the system circuit board 40 of the present disclosure. A processor 42 of the system circuit board 40 can display images on the display panel 10 based on, for example, a signal input from the outside. The processor 42 can cause a display panel 10 to execute any one of, for example, channel switching for images, volume increase, volume decrease, mute, electronic program guide display, image zoom in, image zoom out, or picture-in-picture display based on an input operation command in response to a signal input from the outside.

The system circuit board 40 includes, for example, a reception circuit 41. The reception circuit 41 is configured depending on the type of a signal to be received. For example, in a case where the reception circuit 41 receives a television broadcast signal, the reception circuit 41 includes, for example, an antenna terminal, a digital tuner, and a demultiplexer (not illustrated).

The antenna terminal is a terminal to which the television broadcast signal received by a reception antenna is input. For example, the digital tuner processes the television broadcast signal input to the antenna terminal and outputs a predetermined transport stream corresponding to a channel selected by a user. For example, the demultiplexer extracts a partial transport stream (TS) corresponding to the channel selected by the user from the transport stream obtained by the digital tuner, and outputs the extracted partial TS to the processor 42.

For example, in a case where the reception circuit 41 receives an internet protocol (IP) signal via the internet line, the reception circuit 41 receives the IP signal via the internet line and performs, for example, standard protocol processing in the IP network on the received IP signal. Furthermore, the reception circuit 41 extracts a partial transport stream (TS) corresponding to the channel selected by the user from the signal that has been subjected to the protocol processing, and outputs the extracted partial TS to the processor 42.

For example, in a case where an operation command corresponding to the detection result obtained by a detection signal processing circuit 51 is input by the processor 42, the reception circuit 41 performs processing corresponding to the input operation command on the signal input from the outside. For example, it is assumed that the operation command is channel switching for images. In this case, the reception circuit 41 extracts a partial TS corresponding to the changed channel from the signal input from the outside, and outputs the extracted partial TS to the processor 42. In addition, for example, it is assumed that the operation command is electronic program guide display. In this case, the reception circuit 41 extracts a partial TS corresponding to the program guide from the signal input from the outside, and outputs the extracted partial TS to the processor 42. In addition, for example, it is assumed that the operation command is picture-in-picture display. In this case, the reception circuit 41 extracts a partial TS corresponding to two channels specified in a control signal input to the reception circuit 41 from the signal input from the outside, and outputs the extracted partial TS to the processor 42.

The system circuit board 40 further includes, for example, a processor 42 and a memory 43. The processor 42 controls an operation of each unit of the display 1. For example, the processor 42 stores the partial TS obtained by the reception circuit 41 in the memory 43, and transmits the partial TS read from the memory 43 to a decoder 44. For example, the processor 42 reads an operation command corresponding to the detection result input from the detection signal processing circuit 51 from a table 43A described later, and transmits the read operation command to the reception circuit 41, an image signal processing circuit 45, or an audio signal processing circuit 48.

The memory 43 stores setting information of the display 1 and manages data, for example. The memory 43 can store, for example, the partial TS obtained by the reception circuit 41.

The system circuit board 40 further includes, for example, a decoder 44, an image signal processing circuit 45, a graphics generation circuit 46, an OLED panel drive circuit 47, an audio signal processing circuit 48, a vibration excitation unit drive circuit 49, and a detection signal processing circuit 51.

For example, the decoder 44 can obtain image data by performing decoding processing on an image packetized elementary stream (PES) packet included in the partial TS obtained by the reception circuit 41. In addition, the decoder 44 can obtain, for example, audio data by performing decoding processing on an audio PES packet included in the partial TS obtained by the reception circuit 41.

The image signal processing circuit 45 and the graphics generation circuit 46 perform, for example, multi-image processing, graphics data superimposition processing, and the like on the image data obtained by the decoder 44 as necessary.

The image signal processing circuit 45 performs predetermined processing on image data, and outputs the image data subjected to the predetermined processing to the graphics generation circuit 46. For example, in a case where an operation command corresponding to the detection result obtained by the detection signal processing circuit 51 is input by the processor 42, the image signal processing circuit 45 performs processing on the image data in response to the input operation command. The image signal processing circuit 45 outputs the image data processed according to the operation command input from the processor 42 to the graphics generation circuit 46.

Note that, in the embodiment of the present disclosure, the display 1 is not limited to the form illustrated in FIGS. 1 to 5, and can be appropriately modified.

### 1.2 Background

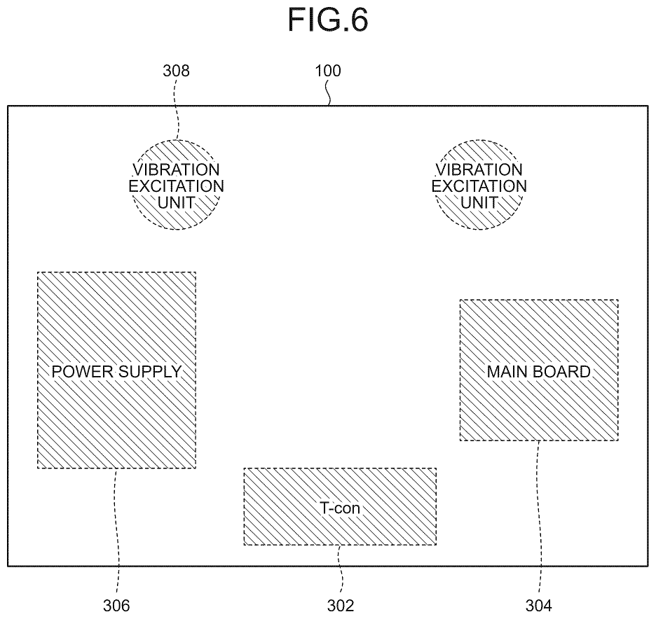

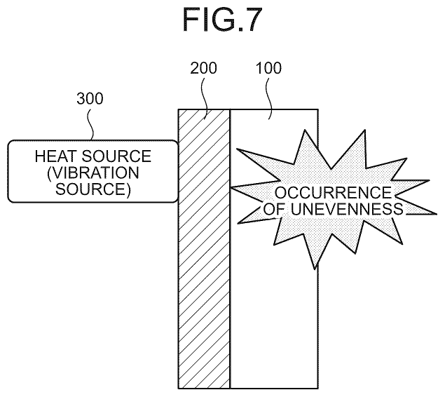

Next, with reference to FIGS. 6 and 7, the background leading to the creation of the embodiments of the present disclosure by the present inventors will be described. FIGS. 6 and 7 are explanatory diagrams for explaining the background of the embodiments of the present disclosure.

As described above, in the display (display device) 1, the vibration excitation units, the system circuit, and the like are provided as various drive units that are provided on the back surface side of the display panel and drive the display panel. Specifically, as illustrated in FIG. 6, vibration excitation units 308 that vibrate the display panel and a display control unit (timing controller: T-con) 302 that controls display by a display panel 100 are provided on the back surface side of the display panel 100 having a plurality of organic EL elements. In addition, a main control unit 304 that controls the vibration excitation units 308 and the display control unit 302, and a power supply unit (power supply) 306 that supplies power to the display panel 100, the vibration excitation units 308, the display control unit 302, the main control unit 304, and the like are provided on the back surface side of the display panel 100. Note that the vibration excitation units 308, the display control unit 302, the main control unit 304, and the power supply unit 306 correspond to the specific examples of a “drive unit” of the present disclosure that drives the display panel 100.

Then, as illustrated in FIG. 7, due to the vibration of the vibration excitation units 308 (vibration source), heat is locally generated in the display panel 100 (for example, about 50° C. to 60° C.), and a temperature difference of about 10° C. may occur in the entire display panel 100. Due to such temperature distribution, color unevenness may occur in the displayed images on the display panel 100.

In addition, similarly, heat is locally generated in the display panel 100 by the display control unit 302 (for example, generates heat higher than 80° C.), the main control unit 304 (for example, generates heat higher than 70° C.), and the power supply unit 306 (for example, generates heat higher than 80° C.), and the like other than the vibration excitation units 308, and color unevenness may thus occur in the displayed images on the display panel 100.

Specifically, the display panel 100 is locally heated by a heat source or vibration source 300 such as the vibration excitation units 308 (here, elements serving as the heat source are collectively referred to as a heat source (vibration source) 300), and the crystal state of an organic material of some organic EL elements on the display panel 100 changes. Then, as the crystal state changes, the conductive characteristics of electrons and holes of the organic material change. As a result, since the conductive characteristics of some of the organic EL elements change, a difference occurs in the characteristics of the organic EL elements in the entire display panel 100, and color unevenness occurs in the displayed images on the display panel 100.

Therefore, in the related art, as illustrated in FIG. 7, the vibration excitation units 308 and the like are dispersedly disposed on the back surface of the display panel 100, and a heat dissipation film 200 made of, for example, a graphite sheet or an aluminum sheet having a film thickness of 1 mm or less is provided on the back surface of the display panel 100, thereby diffusing heat and minimizing occurrence of color unevenness.

However, for example, in a case where the display panel 100 is thick, the output of vibration excitation units 308 is increased in order to vibrate the display panel 100. Therefore, local heating is more likely to occur, and the occurrence of color unevenness cannot be minimized in some cases. That is, even in the related art, there is a limit in minimizing the occurrence of color unevenness.

### 2. SUMMARY OF EMBODIMENTS OF PRESENT DISCLOSURE

Therefore, in view of such a circumstance, the present inventors have studied an organic EL element using a high heat resistance material that is less likely to cause changes in characteristics even at a high temperature, and have created the embodiments of the present disclosure. Hereinafter, the outline of the embodiments of the present disclosure will be described.

It is known that a substance has three states of solid, liquid, and gas, but there is also a state called glass (amorphous) in which molecules and the like are not regularly aligned in contrast to a solid in which molecules and the like are regularly aligned. In a case where the temperature of the substance is increased, the substance transitions from solid to glass, liquid, or gas. The temperature at which the substance is in the glass state is called a glass transition point (Tg).

Therefore, the present inventors have studied the use of a material whose crystal structure is less likely to be changed by heating, that is, a material having a high glass transition point as a material of the organic EL element. According to the studies by the present inventors, as a result of examining the luminance efficiency of organic EL elements using various materials under assumed temperature conditions at the time of use, it has been clarified that the luminance efficiency of an organic EL element is not deteriorated in a case where a material has a glass transition point (Tg) of 120° C. or higher is used.

Therefore, the present inventors have focused on the use of a high glass transition temperature material having a glass transition point of 120° C. or higher for the organic EL element. That is, in the embodiments of the present disclosure created by the present inventors, the organic EL element includes an organic layer containing a high glass transition temperature material having a glass transition point of 120° C. or higher. Then, the present inventors have conceived the use of an organic EL element formed by using an adamantane compound containing adamantane or the like as such a high glass transition temperature material.

Adamantane (C₁₀H₁₆) is a molecule having 10 carbon atoms arranged in the same manner as in a diamond structure and having a cage-like structure as represented by the following Formula (1-1). Adamantane is known to have a high glass transition point and melting point because adamantane has a structure without distortion, is stable, and has a structure with high symmetry since the bond angles of carbons form the natural angle of sp3 carbon (about 109.5 degrees)

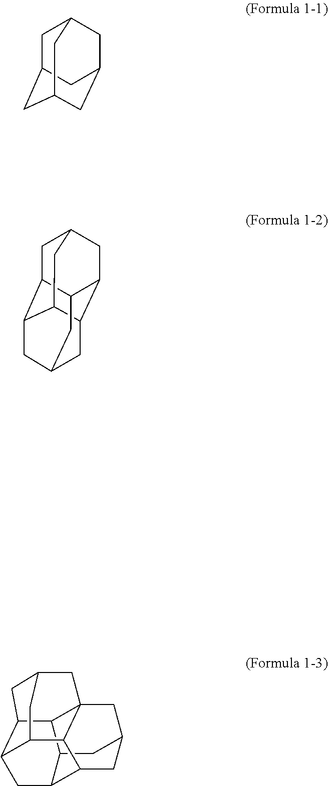

Usually, the glass transition point increases as the molecular weight increases, but adamantane has a higher glass transition point than its molecular weight. Therefore, in the embodiment of the present disclosure, by using the adamantane compound containing adamantane represented by Formula (1) as such a high glass transition temperature material having a high glass transition point, the electrical characteristics (conductive characteristics of electrons and holes) of the organic EL element are less likely to be changed by heat. Therefore, by using the adamantane compound, it is possible to minimize the occurrence of color unevenness in the displayed images on the display panel 100.

Diamantane having a diamond structure as represented by the above-described Formula (1-2) and triamantane having a diamond structure as represented by the above-described Formula (1-3) also have the characteristics similar to those of adamantane. Therefore, in the embodiment of the present disclosure, diamantane and triamantane can also be used in the same manner as adamantane. Note that, in the present specification, the term “diamondoid” is used as a general term for adamantane, diamantane, or triamantane. Furthermore, in the present specification, a compound containing a diamondoid, in other words, a compound having an adamantane structure, a diamantane structure, or a triamantane structure is referred to as a “diamondoid”. In addition, in the present specification, a compound having an adamantane structure represented by the above-described Formula (1-1) is referred to as an “adamantane compound”.

Specifically, in the embodiments of the present disclosure, the organic EL element includes at least one organic layer containing a high glass transition temperature material having a glass transition point of 120° C. or higher as any of layers. The organic layer contains, for example, a diamondoid compound. Furthermore, in the present embodiment, the diamondoid compound can be one diamondoid compound selected from the group consisting of a plurality of diamondoid compounds containing units represented by, for example, the following Formulae (2) to (7), respectively. Furthermore, in the present embodiment, the organic layer is preferably one adamantane compound selected from the group consisting of a plurality of adamantane compounds containing units represented by, for example, the following Formulae (2) to (7), respectively.

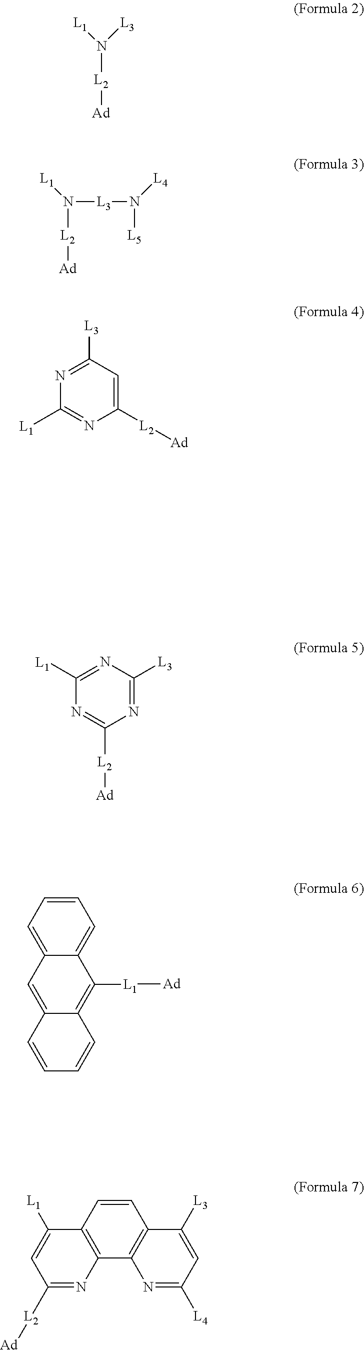

In Formulae (2) to (7), L₁ to L₅ each independently represent a single bond or a linker.

Specifically, the linker can be, for example, a substituted or unsubstituted alkylene group, a substituted or unsubstituted arylene group, a substituted or unsubstituted divalent fused polycyclic aromatic group, a divalent functional group containing one or more substituted or unsubstituted diamondoids (adamantane, diamantane, triamantane), or the like.

Note that, in the present specification, the “substituted or unsubstituted alkylene group” is a divalent group derived by removing one hydrogen atom in an alkyl chain from a “substituted or unsubstituted alkyl group”. In addition, in the present specification, the “substituted or unsubstituted arylene group” is a divalent group derived by removing one hydrogen atom in an aryl ring from a “substituted or unsubstituted aryl group”. In addition, in the present specification, the “divalent fused polycyclic aromatic group” is, for example, a divalent group derived by removing one hydrogen atom from a ring structure forming a skeleton such as a naphthyl group, an anthracenyl group, or a pyrenyl group.

Examples of the alkylene group can include a methylene group, an ethylene group, and an n-propylene group. In addition, examples of the arylene group can include a phenylene group, a biphenylene group, and a terphenylene group. Examples of the divalent fused polycyclic aromatic group can include a naphthylene group and a phenanthrylene group.

The divalent functional group containing one or more substituted or unsubstituted diamondoids is a divalent group that has one or more of the adamantane structure represented by the above-described Formula (1-1), the diamantane structure represented by the above-described Formula (1-2), or the triamantane structure represented by the above-described Formula (1-3), has no substituent or has a substituent at the position of each carbon in the adamantane structure, the diamantane structure, or the triamantane structure, and is derived by removing hydrogen from each of two carbons in the adamantane structure, the diamantane structure, or the triamantane structure. In a case where the divalent functional group has a plurality of adamantane structures, the adamantane structures may have different substituents at different positions, respectively. In addition, in a case where the divalent functional group has a plurality of diamantane structures, the diamantane structures may have different substituents at different positions, respectively. Furthermore, in a case where the divalent functional group has a plurality of triamantane structures, the triamantane structures may have different substituents at different positions, respectively.

In addition, in Formulae (2) to (7), Ad is a monovalent functional group containing one or more substituted or unsubstituted diamondoids (adamantane, diamantane, triamantane). In other words, Ad is a monovalent group that has no substituent or has a substituent at the position of each carbon of the adamantane structure, the diamantane structure, or the triamantane structure, and derived by removing hydrogen from one carbon of one adamantane structure, diamantane structure, or triamantane structure. Note that, in a case where the monovalent functional group has a plurality of adamantane structures, the adamantane structures may have different substituents at different positions, respectively. Note that, in a case where the monovalent functional group has a plurality of adamantane structures, the adamantane structures may have different substituents at different positions, respectively. In addition, in a case where the monovalent functional group has a plurality of diamantane structures, the diamantane structures may have different substituents at different positions, respectively. Note that, in a case where the monovalent functional group has a plurality of diamantane structures, the diamantane structures may have different substituents at different positions, respectively. Furthermore, in a case where the monovalent functional group has a plurality of triamantane structures, the triamantane structures may have different substituents at different positions, respectively. Note that, in a case where the monovalent functional group has a plurality of triamantane structures, the triamantane structures may have different substituents at different positions, respectively.

In the embodiment of the present disclosure, since the organic EL element includes the organic layer containing the high glass transition temperature material having a glass transition point of 120° C. or higher, it is possible to avoid changes in the conductive characteristics of the organic EL element even though the display panel 100 is locally heated by the heat source (vibration source) 300 such as the vibration excitation unit 308. Therefore, in the present embodiment, since there are no differences in the characteristics of the organic EL elements in the entire display panel 100, the occurrence of color unevenness of the displayed images on the display panel 100 can be minimized.

Furthermore, according to the present embodiment, since the characteristics of the organic EL element of the display panel 100 are less likely to be changed by heat, the display panel 100 itself can be made thinner. In addition, according to the present embodiment, since it is not necessary to provide the heat dissipation film 200, the cost of the display 1 can be reduced.

In addition, according to the present embodiment, since the occurrence of color unevenness of the displayed images on the display panel 100 can be minimized even though a larger number of the vibration excitation units 308 or the vibration excitation units 308 with a larger output are attached to the display panel 100, it is possible to achieve audio amplification while maintaining high quality images.

Furthermore, in the present embodiment, by using the diamondoid compound as the high glass transition temperature material having a glass transition point of 120° C. or higher, the display 1 can be manufactured without significantly changing manufacturing processes. That is, according to the present embodiment, the display 1 can be easily manufactured.

Hereinafter, the details of each embodiment of the present disclosure created by the present inventors will be sequentially described.

### 3. FIRST EMBODIMENT

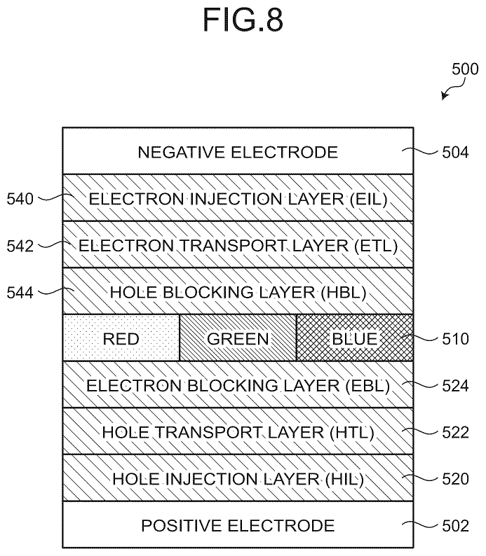

First, a configuration example of an organic EL element 500 according to a first embodiment of the present disclosure will be described with reference to FIG. 8. FIG. 8 is a diagram illustrating a configuration example of the organic EL element 500 of the present embodiment.

As illustrated in FIG. 8, the organic EL element 500 according to the present embodiment has a laminated structure including an emissive layer 510 provided above a substrate (not illustrated), and a positive electrode (first electrode) 502 and a negative electrode (second electrode) 504 with the emissive layer 510 sandwiched therebetween. In addition, the laminated structure includes a hole injection layer 520 provided between the emissive layer 510 and the positive electrode 502, and an electron injection layer 540 provided between the emissive layer 510 and the negative electrode 504.

Furthermore, the laminated structure may include a hole transport layer 522 between the hole injection layer 520 and the emissive layer 510, and may further include an electron blocking layer 524 between the hole transport layer 522 and the emissive layer 510. In addition, the laminated structure may include an electron transport layer 542 between the electron injection layer 540 and the emissive layer 510, and may further include a hole blocking layer 544 between the electron transport layer 542 and the emissive layer 510. That is, in the present embodiment, the laminated structure may not include the hole transport layer 522, the electron blocking layer 524, the electron transport layer 542, and the hole blocking layer 544, or may include some or all of them. Hereinafter, details of each layer of the laminated structure will be described.

Note that, in the present embodiment, it is sufficient that at least one layer of the plurality of layers in the laminated structure constituting the organic EL element 500 contains a diamondoid compound. Furthermore, in the present embodiment, it is preferable that at least one layer of the plurality of layers in the laminated structure constituting the organic EL element 500 contains an adamantane compound.

### (Substrate)

The substrate serving as a support of the organic EL element 500 can be formed of, for example, glass, quartz, plastic, silicon, or the like.

### (Positive Electrode 502)

The positive electrode 502 has a function of injecting holes into the organic EL element 500. The positive electrode 502 can be formed of, for example, a metal with a large work function, an alloy, an electrically conductive compound, and a multilayered body thereof. Examples of the material of the positive electrode 502 include indium tin oxide (ITO), indium zinc oxide (IZO), gold (Au), and platinum (Pt).

### (Hole Injection Layer 520)

The hole injection layer 520 is a layer containing a substance with a high hole-injection property. In the present embodiment, the hole injection layer 520 can contain a diamondoid compound as one of amine compounds with a high hole-injection property. Furthermore, in the present embodiment, the hole injection layer 520 preferably contains an adamantane compound.

Specifically, in the present embodiment, the hole injection layer 520 can contain any one diamondoid compound containing a unit represented by the following Formula (8) or Formula (9).

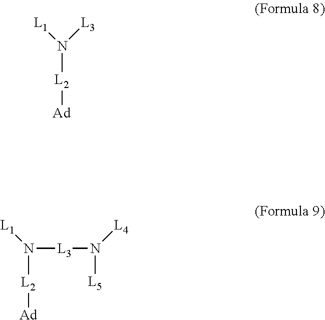

In Formulae (8) and (9), L₁ to L₅ each independently represent a single bond or a linker.

Specifically, the linker can be, for example, a substituted or unsubstituted alkylene group, a substituted or unsubstituted arylene group, a substituted or unsubstituted divalent fused polycyclic aromatic group, a divalent functional group containing one or more substituted or unsubstituted diamondoids (adamantane, diamantane, triamantane), or the like.

Examples of the alkylene group can include a methylene group, an ethylene group, and an n-propylene group. In addition, examples of the arylene group can include a phenylene group, a biphenylene group, and a terphenylene group. Examples of the divalent fused polycyclic aromatic group can include a naphthylene group and a phenanthrylene group.

The divalent functional group containing one or more substituted or unsubstituted diamondoids is a divalent group that has one or more of the adamantane structure represented by the above-described Formula (1-1), the diamantane structure represented by the above-described Formula (1-2), or the triamantane structure represented by the above-described Formula (1-3), has no substituent or has a substituent at the position of each carbon in the adamantane structure, the diamantane structure, or the triamantane structure, and is derived by removing hydrogen from each of two carbons in the adamantane structure, the diamantane structure, or the triamantane structure. In a case where the divalent functional group has a plurality of adamantane structures, the adamantane structures may have different substituents at different positions, respectively. In addition, in a case where the divalent functional group has a plurality of diamantane structures, the diamantane structures may have different substituents at different positions, respectively. Furthermore, in a case where the divalent functional group has a plurality of triamantane structures, the triamantane structures may have different substituents at different positions, respectively.

In addition, in Formulae (8) and (9), Ad is a monovalent functional group containing one or more substituted or unsubstituted diamondoids (adamantane, diamantane, triamantane). In other words, Ad is a monovalent group that has no substituent or has a substituent at the position of each carbon of the adamantane structure, the diamantane structure, or the triamantane structure, and derived by removing hydrogen from one carbon of one adamantane structure, diamantane structure, or triamantane structure. Note that, in a case where the monovalent functional group has a plurality of adamantane structures, the adamantane structures may have different substituents at different positions, respectively. Note that, in a case where the monovalent functional group has a plurality of adamantane structures, the adamantane structures may have different substituents at different positions, respectively. In addition, in a case where the monovalent functional group has a plurality of diamantane structures, the diamantane structures may have different substituents at different positions, respectively. Note that, in a case where the monovalent functional group has a plurality of diamantane structures, the diamantane structures may have different substituents at different positions, respectively. Furthermore, in a case where the monovalent functional group has a plurality of triamantane structures, the triamantane structures may have different substituents at different positions, respectively. Note that, in a case where the monovalent functional group has a plurality of triamantane structures, the triamantane structures may have different substituents at different positions, respectively.

The hole injection layer 520 may or may not contain a dopant. The dopant is a material capable of generating holes in the hole injection layer 520. As the dopant, for example, a compound having an electron withdrawing group (for example, a halogen group or a cyano group) such as a quinodimethane derivative, a chloranil derivative, or a hexaazatriphenylene derivative can be used.

Note that, in the present embodiment, the hole injection layer 520 may be formed of a material other than the above-described materials because it is sufficient that at least one layer of the plurality of layers in the laminated structure constituting the organic EL element 500 contains the diamondoid compound. As a material of the hole injection layer 520, for example, molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, an aromatic amine compound, a polymer compound (such as oligomer, dendrimer, or polymer), or the like can also be used.

### (Hole Transport Layer 522)

The hole transport layer 522 has a function of transporting the holes injected into the hole injection layer 520 to the emissive layer 510 side. The hole transport layer 522 is a layer containing a substance with a high hole-transport property. In the present embodiment, the hole transport layer 522 can contain a diamondoid compound as one of amine compounds with a high hole-transport property.

Specifically, in the present embodiment, the hole transport layer 522 can contain any one diamondoid compound containing a unit represented by the following Formula (10) or Formula (11). Furthermore, in the present embodiment, the hole transport layer 522 preferably contains any one adamantane compound containing a unit represented by the following Formula (10) or Formula (11).

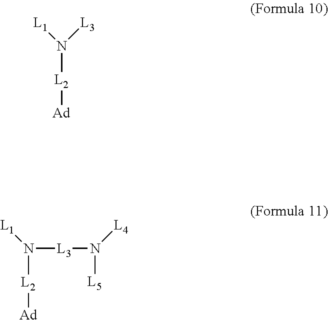

In Formulae (10) and (11), L₁ to L₅ each independently represent a single bond or a linker.

Specifically, the linker can be, for example, a substituted or unsubstituted alkylene group, a substituted or unsubstituted arylene group, a substituted or unsubstituted divalent fused polycyclic aromatic group, a divalent functional group containing one or more substituted or unsubstituted diamondoids (adamantane, diamantane, triamantane), or the like.

Examples of the alkylene group can include a methylene group, an ethylene group, and an n-propylene group. In addition, examples of the arylene group can include a phenylene group, a biphenylene group, and a terphenylene group. Examples of the divalent fused polycyclic aromatic group can include a naphthylene group and a phenanthrylene group.

The divalent functional group containing one or more substituted or unsubstituted diamondoids is a divalent group that has one or more of the adamantane structure represented by the above-described Formula (1-1), the diamantane structure represented by the above-described Formula (1-2), or the triamantane structure represented by the above-described Formula (1-3), has no substituent or has a substituent at the position of each carbon in the adamantane structure, the diamantane structure, or the triamantane structure, and is derived by removing hydrogen from each of two carbons in the adamantane structure, the diamantane structure, or the triamantane structure. In a case where the divalent functional group has a plurality of adamantane structures, the adamantane structures may have different substituents at different positions, respectively. In addition, in a case where the divalent functional group has a plurality of diamantane structures, the diamantane structures may have different substituents at different positions, respectively. Furthermore, in a case where the divalent functional group has a plurality of triamantane structures, the triamantane structures may have different substituents at different positions, respectively.

In addition, in Formulae (10) and (11), Ad is a monovalent functional group containing one or more substituted or unsubstituted diamondoids (adamantane, diamantane, triamantane). In other words, Ad is a monovalent group that has no substituent or has a substituent at the position of each carbon of the adamantane structure, the diamantane structure, or the triamantane structure, and derived by removing hydrogen from one carbon of one adamantane structure, diamantane structure, or triamantane structure. Note that, in a case where the monovalent functional group has a plurality of adamantane structures, the adamantane structures may have different substituents at different positions, respectively. Note that, in a case where the monovalent functional group has a plurality of adamantane structures, the adamantane structures may have different substituents at different positions, respectively. In addition, in a case where the monovalent functional group has a plurality of diamantane structures, the diamantane structures may have different substituents at different positions, respectively. Note that, in a case where the monovalent functional group has a plurality of diamantane structures, the diamantane structures may have different substituents at different positions, respectively. Furthermore, in a case where the monovalent functional group has a plurality of triamantane structures, the triamantane structures may have different substituents at different positions, respectively. Note that, in a case where the monovalent functional group has a plurality of triamantane structures, the triamantane structures may have different substituents at different positions, respectively.

Note that, in the present embodiment, the hole transport layer 522 may be formed of a material other than the above-described materials because it is sufficient that at least one layer of the plurality of layers in the laminated structure constituting the organic EL element 500 contains the diamondoid compound. As the material of the hole transport layer 522, for example, an aromatic amine compound, a carbazole derivative, an anthracene derivative, or the like may be used, and a polymer compound such as poly(N-vinylcarbazole) (abbreviation: PVK) or poly(4-vinyltriphenylamine) (abbreviation: PVTPA) may be used. Note that, in the present embodiment, as the material of the hole transport layer 522, a material other than those described above may be used as long as the material is a substance having a higher hole-transport property than an electron-transport property. Furthermore, in the present embodiment, it is sufficient that the hole transport layer 522 may be a multilayered body in which different materials are layered.

### (Electron Blocking Layer 524)

The electron blocking layer 524 has a function of blocking electrons injected from the negative electrode 504 from passing through the emissive layer 510 and being injected into the hole transport layer 522 without contributing to recombination, thereby confining the holes within the emissive layer 510 The electron blocking layer 524 further has a function of blocking excitation energy obtained in the emissive layer 510 from energy-transferring to the molecules of the hole transport layer 522. That is, the electron blocking layer 524 can block a decrease in the luminance efficiency of the organic EL element 500.

The electron blocking layer 524 is a layer containing a substance with a hole-transport property that is higher than or approximately the same as an electron-transport property, a shallower lowest unoccupied molecular orbital (LUMO) level than the molecules in the emissive layer 510, and a larger band gap. In the present embodiment, the electron blocking layer 524 can contain a diamondoid compound as one of amine compounds with a high hole-transport property.

Specifically, in the present embodiment, the electron blocking layer 524 can contain a diamondoid compound containing a unit represented by the following Formula (12). Furthermore, in the present embodiment, the electron blocking layer 524 preferably contains an adamantane compound containing a unit represented by the following Formula (12).

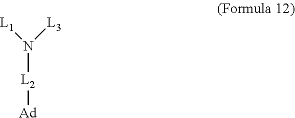

In Formula (12), L₁ to L₃ each independently represent a single bond or a linker.

Specifically, the linker can be, for example, a substituted or unsubstituted alkylene group, a substituted or unsubstituted arylene group, a substituted or unsubstituted divalent fused polycyclic aromatic group, a divalent functional group containing one or more substituted or unsubstituted diamondoids (adamantane, diamantane, triamantane), or the like.

Examples of the alkylene group can include a methylene group, an ethylene group, and an n-propylene group. In addition, examples of the arylene group can include a phenylene group, a biphenylene group, and a terphenylene group. Examples of the divalent fused polycyclic aromatic group can include a naphthylene group and a phenanthrylene group.

The divalent functional group containing one or more substituted or unsubstituted diamondoids is a divalent group that has one or more of the adamantane structure represented by the above-described Formula (1-1), the diamantane structure represented by the above-described Formula (1-2), or the triamantane structure represented by the above-described Formula (1-3), has no substituent or has a substituent at the position of each carbon in the adamantane structure, the diamantane structure, or the triamantane structure, and is derived by removing hydrogen from each of two carbons in the adamantane structure, the diamantane structure, or the triamantane structure. In a case where the divalent functional group has a plurality of adamantane structures, the adamantane structures may have different substituents at different positions, respectively. In addition, in a case where the divalent functional group has a plurality of diamantane structures, the diamantane structures may have different substituents at different positions, respectively. Furthermore, in a case where the divalent functional group has a plurality of triamantane structures, the triamantane structures may have different substituents at different positions, respectively.

In addition, in Formula (12), Ad is a monovalent functional group containing one or more substituted or unsubstituted diamondoids (adamantane, diamantane, triamantane). In other words, Ad is a monovalent group that has no substituent or has a substituent at the position of each carbon of the adamantane structure, the diamantane structure, or the triamantane structure, and derived by removing hydrogen from one carbon of one adamantane structure, diamantane structure, or triamantane structure. Note that, in a case where the monovalent functional group has a plurality of adamantane structures, the adamantane structures may have different substituents at different positions, respectively. Note that, in a case where the monovalent functional group has a plurality of adamantane structures, the adamantane structures may have different substituents at different positions, respectively. In addition, in a case where the monovalent functional group has a plurality of diamantane structures, the diamantane structures may have different substituents at different positions, respectively. Note that, in a case where the monovalent functional group has a plurality of diamantane structures, the diamantane structures may have different substituents at different positions, respectively. Furthermore, in a case where the monovalent functional group has a plurality of triamantane structures, the triamantane structures may have different substituents at different positions, respectively. Note that, in a case where the monovalent functional group has a plurality of triamantane structures, the triamantane structures may have different substituents at different positions, respectively.

Note that, in the present embodiment, the electron blocking layer 524 may be formed of a material other than the above-described materials because it is sufficient that at least one layer of the plurality of layers in the laminated structure constituting the organic EL element 500 contains the diamondoid compound. As the material of the electron blocking layer 524, for example, an aromatic amine derivative, a carbazole derivative, a 9,10-dihydroacridine derivative, a benzofuran derivative, a benzothiophene derivative, or the like may be used.

### (Emissive Layer 510)

The emissive layer 510 is a layer in which light emission can occur by recombination of holes and electrons. In the present embodiment, the emissive layer 510 can emit any one of blue light, red light, green light, yellow light, or cyan light. In addition, in the present embodiment, two or more emissive layers 510 that emit light of different colors may be layered in the organic EL element 500.

The emissive layer 510 contains a highly luminescent substance (dopant), and for example, a fluorescent compound that emits fluorescence or a phosphorescent compound that emits phosphorescence can be used as the highly luminescent substance. The fluorescent compound is a compound capable of emitting light from a singlet excited state, and the phosphorescent compound is a compound capable of emitting light from a triplet excited state. Then, in the emissive layer 510, the above-described highly luminescent substance (dopant) may be dispersed in a host material. The host material is preferably a material having a higher lowest unoccupied molecular orbital (LUMO) level and a lower highest occupied molecular orbital (HOMO) level than those of the highly luminescent substance.

In the present embodiment, an emissive layer 510 that emits blue light can contain a diamondoid compound containing a unit represented by the following Formula (13) as the dopant or the host material. Furthermore, in the present embodiment, the emissive layer 510 that emits blue light preferably contains an adamantane compound containing a unit represented by the following Formula (13) as the dopant or the host material.

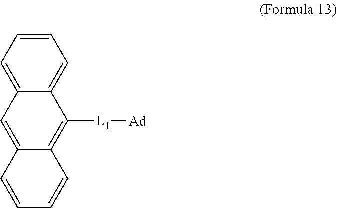

In Formula (13), L₁ represents a single bond or a linker.

Specifically, the linker can be, for example, a substituted or unsubstituted alkylene group, a substituted or unsubstituted arylene group, a substituted or unsubstituted divalent fused polycyclic aromatic group, a divalent functional group containing one or more substituted or unsubstituted diamondoids (adamantane, diamantane, triamantane), or the like.

Examples of the alkylene group can include a methylene group, an ethylene group, and an n-propylene group. In addition, examples of the arylene group can include a phenylene group, a biphenylene group, and a terphenylene group. Examples of the divalent fused polycyclic aromatic group can include a naphthylene group and a phenanthrylene group.

The divalent functional group containing one or more substituted or unsubstituted diamondoids is a divalent group that has one or more of the adamantane structure represented by the above-described Formula (1-1), the diamantane structure represented by the above-described Formula (1-2), or the triamantane structure represented by the above-described Formula (1-3), has no substituent or has a substituent at the position of each carbon in the adamantane structure, the diamantane structure, or the triamantane structure, and is derived by removing hydrogen from each of two carbons in the adamantane structure, the diamantane structure, or the triamantane structure. In a case where the divalent functional group has a plurality of adamantane structures, the adamantane structures may have different substituents at different positions, respectively. In addition, in a case where the divalent functional group has a plurality of diamantane structures, the diamantane structures may have different substituents at different positions, respectively. Furthermore, in a case where the divalent functional group has a plurality of triamantane structures, the triamantane structures may have different substituents at different positions, respectively.

In addition, in Formula (13), Ad is a monovalent functional group containing one or more substituted or unsubstituted diamondoids (adamantane, diamantane, triamantane). In other words, Ad is a monovalent group that has no substituent or has a substituent at the position of each carbon of the adamantane structure, the diamantane structure, or the triamantane structure, and derived by removing hydrogen from one carbon of one adamantane structure, diamantane structure, or triamantane structure. Note that, in a case where the monovalent functional group has a plurality of adamantane structures, the adamantane structures may have different substituents at different positions, respectively. Note that, in a case where the monovalent functional group has a plurality of adamantane structures, the adamantane structures may have different substituents at different positions, respectively. In addition, in a case where the monovalent functional group has a plurality of diamantane structures, the diamantane structures may have different substituents at different positions, respectively. Note that, in a case where the monovalent functional group has a plurality of diamantane structures, the diamantane structures may have different substituents at different positions, respectively. Furthermore, in a case where the monovalent functional group has a plurality of triamantane structures, the triamantane structures may have different substituents at different positions, respectively. Note that, in a case where the monovalent functional group has a plurality of triamantane structures, the triamantane structures may have different substituents at different positions, respectively.

In addition, in the present embodiment, an emissive layer 510 that emits red light and an emissive layer 510 that emits green light may also contain diamondoid compounds similarly. Furthermore, in the present embodiment, the emissive layer 510 that emits red light and the emissive layer 510 that emits green light also preferably contain adamantane compounds similarly.

Note that, in the present embodiment, the emissive layer 510 may be formed of a material other than the above-described materials because it is sufficient that at least one layer of the plurality of layers in the laminated structure constituting the organic EL element 500 contains the diamondoid compound. For example, in the present embodiment, the emissive layer 510 may contain the following materials. Specifically, as a blue fluorescent material that can be used for the emissive layer 510, for example, a pyrene derivative, a styrylamine derivative, a chrysene derivative, a fluoranthene derivative, a fluorene derivative, a diamine derivative, a triarylamine derivative, or the like can be used. In addition, as a green fluorescent material that can be used for the emissive layer 510, for example, an aromatic amine derivative or the like can be used. Furthermore, as a red fluorescent material that can be used for the emissive layer 510, for example, a tetracene derivative, a diamine derivative, or the like can be used.

Furthermore, as a blue phosphorescent material that can be used for the emissive layer 510, for example, a metal complex such as an iridium complex, an osmium complex, a platinum complex, or the like can be used. In addition, as a green phosphorescent material that can be used for the emissive layer 510, for example, an iridium complex or the like can be used. Furthermore, as a red phosphorescent material that can be used for the emissive layer 510, for example, a metal complex such as an iridium complex, a platinum complex, a terbium complex, a europium complex, or the like can be used.

In addition, as the host material, for example, a metal complex such as an aluminum complex, a beryllium complex, or a zinc complex, a heterocyclic compound such as an oxadiazole derivative, a benzimidazole derivative, or a phenanthroline derivative, a fused aromatic compound such as a carbazole derivative, an anthracene derivative, a phenanthrene derivative, a pyrene derivative, or a chrysene derivative, or an aromatic amine compound such as a triarylamine derivative or a fused polycyclic aromatic amine derivative can also be used.

### (Hole Blocking Layer 544)

The hole blocking layer 544 has a function of blocking holes injected from the positive electrode 502 from passing through the emissive layer 510 and being injected into the electron transport layer 542 without contributing to recombination, thereby confining the holes within the emissive layer 510 The hole blocking layer 544 further has a function of blocking excitation energy obtained in the emissive layer 510 from energy-transferring to the molecules in the electron transport layer 542. That is, the hole blocking layer 544 can block a decrease in the luminance efficiency of the organic EL element 500.

The hole blocking layer 544 preferably has an electron-transport property higher than or about the same as the hole-transport property, it is preferable to use a material that has a deeper HOMO level and a larger band gap than the molecules in the emissive layer 510.

Specifically, in the present embodiment, the hole blocking layer 544 can contain any one diamondoid compound containing a unit represented by the following Formula (14) or Formula (15). Furthermore, in the present embodiment, the hole blocking layer 544 preferably contains any one adamantane compound containing a unit represented by the following Formula (14) or Formula (15).

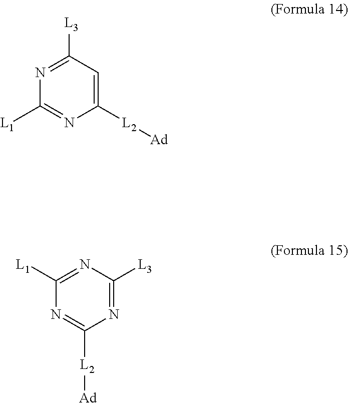

In Formula (14) or Formula (15), L₁ to L₃ represent a single bond or a linker.

Specifically, the linker can be, for example, a substituted or unsubstituted alkylene group, a substituted or unsubstituted arylene group, a substituted or unsubstituted divalent fused polycyclic aromatic group, a divalent functional group containing one or more substituted or unsubstituted diamondoids (adamantane, diamantane, triamantane), or the like.

Examples of the alkylene group can include a methylene group, an ethylene group, and an n-propylene group. In addition, examples of the arylene group can include a phenylene group, a biphenylene group, and a terphenylene group. Examples of the divalent fused polycyclic aromatic group can include a naphthylene group and a phenanthrylene group.

The divalent functional group containing one or more substituted or unsubstituted diamondoids is a divalent group that has one or more of the adamantane structure represented by the above-described Formula (1-1), the diamantane structure represented by the above-described Formula (1-2), or the triamantane structure represented by the above-described Formula (1-3), has no substituent or has a substituent at the position of each carbon in the adamantane structure, the diamantane structure, or the triamantane structure, and is derived by removing hydrogen from each of two carbons in the adamantane structure, the diamantane structure, or the triamantane structure. In a case where the divalent functional group has a plurality of adamantane structures, the adamantane structures may have different substituents at different positions, respectively. In addition, in a case where the divalent functional group has a plurality of diamantane structures, the diamantane structures may have different substituents at different positions, respectively. Furthermore, in a case where the divalent functional group has a plurality of triamantane structures, the triamantane structures may have different substituents at different positions, respectively.

In addition, in Formulae (14) and (15), Ad is a monovalent functional group containing one or more substituted or unsubstituted diamondoids (adamantane, diamantane, triamantane). In other words, Ad is a monovalent group that has no substituent or has a substituent at the position of each carbon of the adamantane structure, the diamantane structure, or the triamantane structure, and derived by removing hydrogen from one carbon of one adamantane structure, diamantane structure, or triamantane structure. Note that, in a case where the monovalent functional group has a plurality of adamantane structures, the adamantane structures may have different substituents at different positions, respectively. Note that, in a case where the monovalent functional group has a plurality of adamantane structures, the adamantane structures may have different substituents at different positions, respectively. In addition, in a case where the monovalent functional group has a plurality of diamantane structures, the diamantane structures may have different substituents at different positions, respectively. Note that, in a case where the monovalent functional group has a plurality of diamantane structures, the diamantane structures may have different substituents at different positions, respectively. Furthermore, in a case where the monovalent functional group has a plurality of triamantane structures, the triamantane structures may have different substituents at different positions, respectively. Note that, in a case where the monovalent functional group has a plurality of triamantane structures, the triamantane structures may have different substituents at different positions, respectively.

Note that, in the present embodiment, the hole blocking layer 544 may be formed of a material other than the above-described materials because it is sufficient that at least one layer of the plurality of layers in the laminated structure constituting the organic EL element 500 contains the diamondoid compound. As the material of the hole blocking layer 544, for example, a metal complex such as a phenanthroline derivative, an oxadiazole derivative, a triazole derivative, bis(2-methyl-8-quinolinolato) (4-hydroxy-biphenylyl)aluminum, or the like may be used.

### (Electron Transport Layer 542)

The electron transport layer 542 has a function of transporting the electrons injected from the negative electrode 504 into the electron injection layer 540 to the emissive layer 510 side. The electron transport layer 542 is a layer containing a substance with a high electron-transport property.

Specifically, in the present embodiment, the electron transport layer 542 can contain a diamondoid compound with a high electron-transport property. In addition, the diamondoid compound can be one diamondoid compound selected from the group consisting of a plurality of diamondoid compounds containing units represented by the following Formulae (16) to (18), respectively. Furthermore, in the present embodiment, the electron transport layer 542 preferably contains one adamantane compound selected from the group consisting of the plurality of adamantane compounds containing units represented by the following Formulae (16) to (18), respectively.

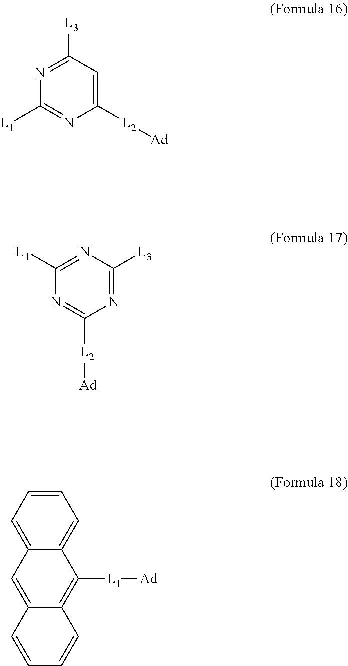

In Formulae (16) to (18), L₁ to L₃ each independently represent a single bond or a linker.

Specifically, the linker can be, for example, a substituted or unsubstituted alkylene group, a substituted or unsubstituted arylene group, a substituted or unsubstituted divalent fused polycyclic aromatic group, a divalent functional group containing one or more substituted or unsubstituted diamondoids (adamantane, diamantane, triamantane), or the like.

Examples of the alkylene group can include a methylene group, an ethylene group, and an n-propylene group. In addition, examples of the arylene group can include a phenylene group, a biphenylene group, and a terphenylene group. Examples of the divalent fused polycyclic aromatic group can include a naphthylene group and a phenanthrylene group.

The divalent functional group containing one or more substituted or unsubstituted diamondoids is a divalent group that has one or more of the adamantane structure represented by the above-described Formula (1-1), the diamantane structure represented by the above-described Formula (1-2), or the triamantane structure represented by the above-described Formula (1-3), has no substituent or has a substituent at the position of each carbon in the adamantane structure, the diamantane structure, or the triamantane structure, and is derived by removing hydrogen from each of two carbons in the adamantane structure, the diamantane structure, or the triamantane structure. In a case where the divalent functional group has a plurality of adamantane structures, the adamantane structures may have different substituents at different positions, respectively. In addition, in a case where the divalent functional group has a plurality of diamantane structures, the diamantane structures may have different substituents at different positions, respectively. Furthermore, in a case where the divalent functional group has a plurality of triamantane structures, the triamantane structures may have different substituents at different positions, respectively.

In addition, in Formulae (16) to (18), Ad is a monovalent functional group containing one or more substituted or unsubstituted diamondoids (adamantane, diamantane, triamantane). In other words, Ad is a monovalent group that has no substituent or has a substituent at the position of each carbon of the adamantane structure, the diamantane structure, or the triamantane structure, and derived by removing hydrogen from one carbon of one adamantane structure, diamantane structure, or triamantane structure. Note that, in a case where the monovalent functional group has a plurality of adamantane structures, the adamantane structures may have different substituents at different positions, respectively. Note that, in a case where the monovalent functional group has a plurality of adamantane structures, the adamantane structures may have different substituents at different positions, respectively. In addition, in a case where the monovalent functional group has a plurality of diamantane structures, the diamantane structures may have different substituents at different positions, respectively. Note that, in a case where the monovalent functional group has a plurality of diamantane structures, the diamantane structures may have different substituents at different positions, respectively. Furthermore, in a case where the monovalent functional group has a plurality of triamantane structures, the triamantane structures may have different substituents at different positions, respectively. Note that, in a case where the monovalent functional group has a plurality of triamantane structures, the triamantane structures may have different substituents at different positions, respectively.

Note that, in the present embodiment, the electron transport layer 542 may be formed of a material other than the above-described materials because it is sufficient that at least one layer of the plurality of layers in the laminated structure constituting the organic EL element 500 contains the diamondoid compound. As the material of the electron transport layer 542, for example, a metal complex such as an aluminum complex, a beryllium complex, or a zinc complex, a heteroaromatic compound such as an imidazole derivative, a benzimidazole derivative, an azine derivative, a carbazole derivative, or a phenanthroline derivative, a polymer compound, or the like can be used.

In addition, the electron transport layer 542 may or may not contain a lithium complex.

### (Electron Injection Layer 540)

The electron injection layer 540 has a function of promoting injection of electrons from the negative electrode 504. The electron injection layer 540 is a layer containing a substance with a high electron-injection property. For the electron injection layer 540, for example, a metal complex compound such as lithium (Li), ytterbium (Yb), lithium fluoride (LiF), cesium fluoride (CsF), calcium fluoride (CaF₂), or 8-hydroxyquinolinolato-lithium (Liq), an alkali metal such as a lithium oxide (LiOx), an alkaline earth metal, or a compound thereof can be used.

In addition, in the present embodiment, the electron injection layer 540 may contain a diamondoid compound.

### (Negative Electrode 504)

The negative electrode 504 has a function of injecting electrons into the organic EL element 500. It is preferable to use, as the negative electrode 504, a metal with a large work function, an alloy, an electrically conductive compound, and a multilayered body thereof. Examples of such a material of the negative electrode 504 include alkali metals such as lithium (Li) and cesium (Cs), alkaline earth metals such as magnesium (Mg), calcium (Ca), and strontium (Sr), and alloys containing these metals (for example, MgAg and AlLi), rare earth metals such as europium (Eu) and ytterbium (Yb), and alloys containing these metals.

In addition, for the negative electrode 504, various conductive materials such as aluminum, silver (Ag), ITO, and graphene may be used.

Note that, in the present embodiment, a film thickness of each layer of the laminated structure of the organic EL element 500 is not particularly limited, but is preferably within a range of several nm to 1 μm in general in order to minimize defects such as pinholes, control the applied voltage to be low, and improve the luminance efficiency.

Note that the configuration of the organic EL element 500 according to the present embodiment is not limited to the configuration illustrated in FIG. 8.

As described above, in the present embodiment, since the organic EL element 500 includes at least one organic layer containing the high glass transition temperature material having a glass transition point of 120° C. or higher, it is possible to avoid changes in the conductive characteristics of the organic EL element 500 even though the display panel 100 is locally heated by the heat source (vibration source) 300 such as the vibration excitation unit 308. Therefore, in the present embodiment, since there are no differences in the characteristics of the organic EL elements 500 in the entire display panel 100, the occurrence of color unevenness of the displayed images on the display panel 100 can be minimized.

Furthermore, in the present embodiment, by using the diamondoid compound as the high glass transition temperature material having a glass transition point of 120° C. or higher, the display 1 can be manufactured without significantly changing manufacturing processes. That is, according to the present embodiment, the display 1 can be easily manufactured.

### 4. SECOND EMBODIMENT

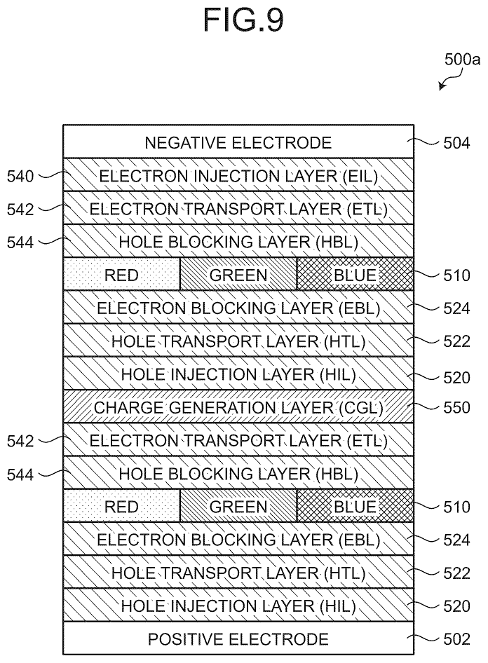

Next, a configuration example of an organic EL element 500a according to a second embodiment of the present disclosure will be described with reference to FIG. 9. FIG. 9 is a diagram illustrating a configuration example of the organic EL element 500a of the present embodiment. In the present embodiment, the organic EL element 500a that has a tandem structure in which two or more laminated structures of the organic EL elements 500 according to the first embodiment described above are stacked will be described. With such a tandem structure, the organic EL element 500a according to the present embodiment can efficiently emit stronger light with a small current.

As illustrated in FIG. 9, in the organic EL element 500a according to the present embodiment, two laminated structures are stacked, each including a hole injection layer 520, a hole transport layer 522, an electron blocking layer 524, an emissive layer 510, a hole blocking layer 544, and an electron transport layer 542, which are sequentially layered. Furthermore, in the present embodiment, the two laminated structures are sandwiched between a positive electrode 502, and an electron injection layer 540 and a negative electrode 504, and a charge generation layer 550 is provided between the two laminated structures. Note that, in the present embodiment, the number of laminated structures is not limited to two, and is not particularly limited as long as two or more laminated structures are stacked. In addition, in the present embodiment, it is sufficient that at least one layer of a plurality of layers in the laminated structures constituting the organic EL element 500a contains a diamondoid compound. Furthermore, in the present embodiment, it is preferable that at least one layer of the plurality of layers in the laminated structures constituting the organic EL element 500a contains an adamantane compound.

Hereinafter, the details of each layer of the above-described laminated structures will be described, but in the present embodiment, each layer denoted by the same reference numeral as that of the first embodiment can have the same function as that of each layer in the first embodiment and can be formed of the same material, and thus the description of details of the same layer will not be repeated here.

### (Emissive Layer 510)

Note that, in the present embodiment, it is assumed that the emissive layer 510 can emit any one of blue light, red light, green light, yellow light, or cyan light. In addition, in the present embodiment, two or more laminated structures may have emissive layers 510 that emit light of different colors.

### (Charge Generation Layer 550)

The charge generation layer 550 is a layer having a function of generating a charge.

In the present embodiment, the charge generation layer 550 may contain a diamondoid compound. Furthermore, the diamondoid compound is a diamondoid compound containing a unit represented by the following Formula (19). Furthermore, in the present embodiment, the charge generation layer 550 preferably contains an adamantane compound containing a unit represented by the following Formula (19).

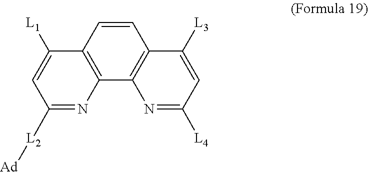

In Formula (19), L₁ to L₄ each independently represent a single bond or a linker.

Specifically, the linker can be, for example, a substituted or unsubstituted alkylene group, a substituted or unsubstituted arylene group, a substituted or unsubstituted divalent fused polycyclic aromatic group, a divalent functional group containing one or more substituted or unsubstituted diamondoids (adamantane, diamantane, triamantane), or the like.

Examples of the alkylene group can include a methylene group, an ethylene group, and an n-propylene group. In addition, examples of the arylene group can include a phenylene group, a biphenylene group, and a terphenylene group. Examples of the divalent fused polycyclic aromatic group can include a naphthylene group and a phenanthrylene group.

The divalent functional group containing one or more substituted or unsubstituted diamondoids is a divalent group that has one or more of the adamantane structure represented by the above-described Formula (1-1), the diamantane structure represented by the above-described Formula (1-2), or the triamantane structure represented by the above-described Formula (1-3), has no substituent or has a substituent at the position of each carbon in the adamantane structure, the diamantane structure, or the triamantane structure, and is derived by removing hydrogen from each of two carbons in the adamantane structure, the diamantane structure, or the triamantane structure. In a case where the divalent functional group has a plurality of adamantane structures, the adamantane structures may have different substituents at different positions, respectively. In addition, in a case where the divalent functional group has a plurality of diamantane structures, the diamantane structures may have different substituents at different positions, respectively. Furthermore, in a case where the divalent functional group has a plurality of triamantane structures, the triamantane structures may have different substituents at different positions, respectively.

In addition, in Formula (19), Ad is a monovalent functional group containing one or more substituted or unsubstituted diamondoids (adamantane, diamantane, triamantane). In other words, Ad is a monovalent group that has no substituent or has a substituent at the position of each carbon of the adamantane structure, the diamantane structure, or the triamantane structure, and derived by removing hydrogen from one carbon of one adamantane structure, diamantane structure, or triamantane structure. Note that, in a case where the monovalent functional group has a plurality of adamantane structures, the adamantane structures may have different substituents at different positions, respectively. Note that, in a case where the monovalent functional group has a plurality of adamantane structures, the adamantane structures may have different substituents at different positions, respectively. In addition, in a case where the monovalent functional group has a plurality of diamantane structures, the diamantane structures may have different substituents at different positions, respectively. Note that, in a case where the monovalent functional group has a plurality of diamantane structures, the diamantane structures may have different substituents at different positions, respectively. Furthermore, in a case where the monovalent functional group has a plurality of triamantane structures, the triamantane structures may have different substituents at different positions, respectively. Note that, in a case where the monovalent functional group has a plurality of triamantane structures, the triamantane structures may have different substituents at different positions, respectively.

Note that, in the present embodiment, the charge generation layer 550 may be formed of a material other than the above-described materials because it is sufficient that at least one layer of the plurality of layers in the laminated structures constituting the organic EL element 500 contains the diamondoid compound. As the material of the charge generation layer 550, for example, a metal complex such as an aluminum complex, a beryllium complex, or a zinc complex, a heteroaromatic compound such as an imidazole derivative, a benzimidazole derivative, an azine derivative, a carbazole derivative, or a phenanthroline derivative, a polymer compound, or the like can be used.

In addition, the charge generation layer 550 may or may not contain a lithium complex.

Note that the configuration of the organic EL element 500a according to the present embodiment is not limited to the configuration illustrated in FIG. 9.

As described above, in the present embodiment, since the organic EL element 500a includes at least one organic layer containing the high glass transition temperature material having a glass transition point of 120° C. or higher, it is possible to avoid changes in the conductive characteristics of the organic EL element 500a even though the display panel 100 is locally heated by the vibration source such as the vibration excitation unit 308 or the heat source 300. Therefore, in the present embodiment, since there are no differences in the characteristics of the organic EL elements 500a in the entire display panel 100, the occurrence of color unevenness of the displayed images on the display panel 100 can be minimized.

Furthermore, in the present embodiment, by using the diamondoid compound as the high glass transition temperature material having a glass transition point of 120° C. or higher, the display 1 can be manufactured without significantly changing manufacturing processes. That is, according to the present embodiment, the display 1 can be easily manufactured.

### 5. THIRD EMBODIMENT

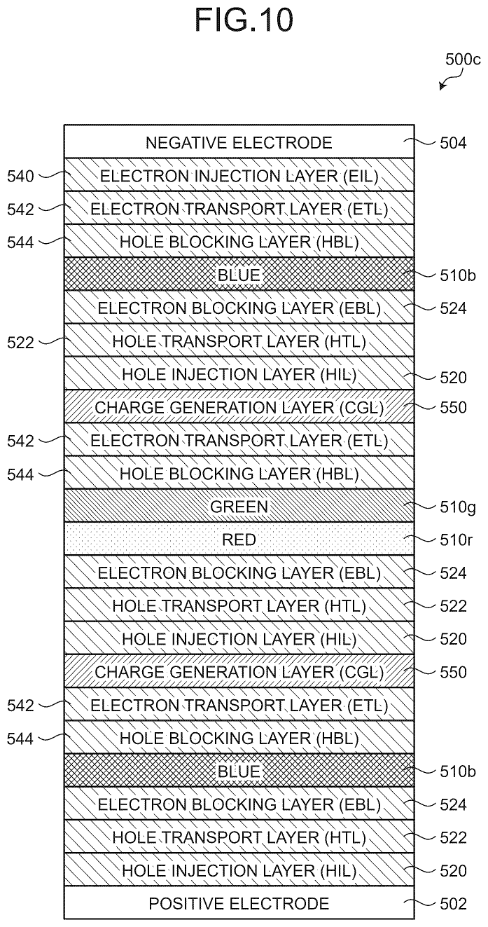

Next, a configuration example of an organic EL element 500c according to a third embodiment of the present disclosure will be described with reference to FIG. 10. FIG. 10 is a diagram illustrating a configuration example of the organic EL element 500c of the present embodiment. In the present embodiment, the organic EL element 500c that has a tandem structure in which two or more laminated structures of the organic EL elements 500 according to the first embodiment described above are stacked, and that emits white light will be described.

As illustrated in FIG. 10, in the organic EL element 500c according to the present embodiment, three laminated structures are stacked, each including a hole transport layer 522, an electron blocking layer 524, an emissive layer 510, a hole blocking layer 544, and an electron transport layer 542, which are sequentially layered. Furthermore, in the present embodiment, the three laminated structures are sandwiched between a positive electrode 502 and a hole injection layer 520, and an electron injection layer 540 and a negative electrode 504, and charge generation layers 550 are provided between the laminated structures in the same manner as in the second embodiment.

Furthermore, in the present embodiment, an emissive layer 510 of the uppermost laminated structure and an emissive layer 510 of the lowermost laminated structure are emissive layers 510b that emit blue light, and an emissive layer 510 of a laminated structure in the middle is formed with a multilayered body of an emissive layer 510r that emits red light and an emissive layer 510g that emits green light. Note that, in the present embodiment, the layering order of the emissive layer 510r that emits red light and the emissive layer 510g that emits green light is not limited to the order illustrated in FIG. 10. As described above, in the present embodiment, since one organic EL element 500c includes the emissive layers 510b, 510g, and 510r that emit blue light, red light, and green light, the organic EL element 500c can emit white light due to the color mixing of these lights. In addition, in the present embodiment, the emissive layer 510 of the laminated structure in the middle may be an emissive layer 510 that emits yellow light.

Note that, in the present embodiment, the number of laminated structures is not limited to three, and is not particularly limited as long as two or more laminated structures are stacked. In addition, in the present embodiment, it is sufficient that at least one layer of a plurality of layers in the laminated structures constituting the organic EL element 500c contains a diamondoid compound. Furthermore, in the present embodiment, it is preferable that at least one layer of the plurality of layers in the laminated structures constituting the organic EL element 500c contains an adamantane compound.

Note that, in the present embodiment, each layer denoted by the same reference numeral as those of the first and second embodiments can have the same function as that of each layer in the first and second embodiments and can be formed of the same material, and thus the description of details of the same layer will not be repeated here.

Note that the configuration of the organic EL element 500c according to the present embodiment is not limited to the configuration illustrated in FIG. 10.

As described above, in the present embodiment, since the organic EL element 500c includes at least one organic layer containing the high glass transition temperature material having a glass transition point of 120° C. or higher, it is possible to avoid changes in the conductive characteristics of the organic EL element 500c even though the display panel 100 is locally heated by the vibration source such as the vibration excitation unit 308 or the heat source 300. Therefore, in the present embodiment, since there are no differences in the characteristics of the organic EL elements 500c in the entire display panel 100, the occurrence of color unevenness of the displayed images on the display panel 100 can be minimized.

### 6. Fourth Embodiment

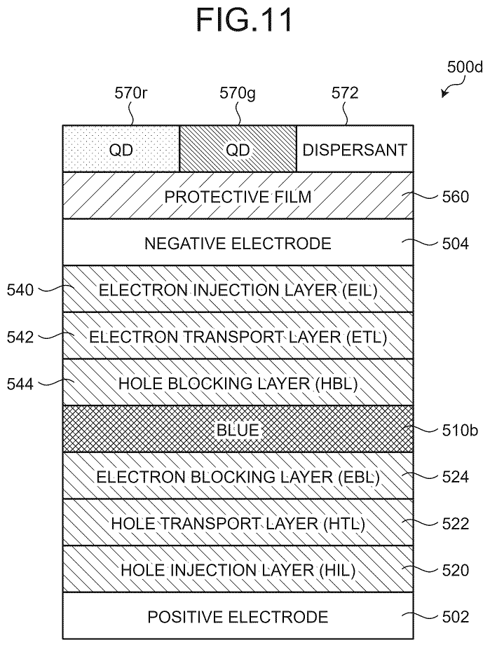

Next, a configuration example of an organic EL element 500d according to a fourth embodiment of the present disclosure will be described with reference to FIG. 11. FIG. 11 is a diagram illustrating a configuration example of the organic EL element 500d of the present embodiment. In the present embodiment, although the organic EL element 500d has a configuration similar to that of the first embodiment, the emissive layer 510 includes an emissive layer 510b that emits blue light, and the blue light is converted into red light or green light by a quantum dot layer 570 provided on a laminated structure of the organic EL element 500d. In the present embodiment, by using such a quantum dot layer 570, light having a wavelength with a narrow spectral width and a sharp peak, that is, light with high color purity can be obtained.

The quantum dot layer 570 contains fine particles having a particle diameter of several nm to 20 nm, that is, quantum dots. The quantum dots exhibit optical properties owing to a quantum confinement effect (quantum size effect) with which electrons and excitons are confined in nanometer-sized small crystals. For example, a quantum dot can emit light (here, red light or green light) having a longer wavelength than excitation light when excited by the excitation light (here, blue light from the emissive layer 510g). Furthermore, the wavelength of the emitted light can be freely controlled by the particle diameter of the quantum dot.

Note that, in the present embodiment, since light with a longer wavelength has higher energy, blue light can be used as excitation light to efficiently obtain red light and green light from the quantum dots.

As illustrated in FIG. 11, the organic EL element 500d according to the present embodiment has a laminated structure including a hole injection layer 520, a hole transport layer 522, an electron blocking layer 524, an emissive layer 510b that emits blue light, a hole blocking layer 544, an electron transport layer 542, and an electron injection layer 540, which are sequentially layered. In addition, in the organic EL element 500d, the laminated structure is sandwiched between a positive electrode 502 and a negative electrode 504. Note that, in the present embodiment, it is sufficient that at least one layer of a plurality of layers in the laminated structure or the quantum dot layer 570 constituting the organic EL element 500d contains a diamondoid compound.

Furthermore, in the present embodiment, a protective film 560 is formed on the negative electrode 504, and quantum dot layers 570r and 570g and a dispersant 572 are provided on the protective film 560.

Hereinafter, the details of each layer of the organic EL element 500d will be described, but in the present embodiment, each layer denoted by the same reference numeral as that of the first embodiment can have the same function as that of each layer in the first embodiment and can be formed of the same material, and thus the description of details of the same layer will not be repeated here.

### (Emissive Layer 510b)

In the present embodiment, the emissive layer 510b can emit blue light.

### (Protective Film 560)

The protective film 560 is formed of, for example, a nitride film such as silicon nitride (SiN), an oxide film such as silicon oxynitride (SiON) or aluminum oxide (AlOx), a transparent organic film, a multilayer film thereof, or the like. Note that the protective film 560 may be a multilayered body including layers made of different materials.

### (Quantum Dot Layers 570g and 570r)

A quantum dot layer 570g can emit green light by blue light from the emissive layer 510b, and a quantum dot layer 570r can emit red light by blue light from the emissive layer 510b. Note that, in the present embodiment, the quantum dot layer 570 may emit yellow light or cyan light.

Examples of the material of the quantum dot layer 570 include semiconductor compounds such as group II-VI semiconductor compounds such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe, group III-V semiconductor compounds such as AlN, AlP, AlAs, AlSb, GaAs, GaP, GaN, GaSb, InN, InAs, InP, InSb, TiN, TiP, TiAs, and TiSb, and group IV semiconductors such as Si, Ge, and Pb.

In addition, in the present embodiment, the quantum dot layers 570g and 570r may contain diamondoid compounds. Furthermore, in the present embodiment, the quantum dot layers 570g and 570r preferably contain adamantane compounds.

### (Dispersant 572)

The dispersant 572 is formed of, for example, a resin such as a styrene resin, an acrylic resin, a styrene-acrylic copolymer resin, or a siloxane resin, and can disperse light.

Note that the configuration of the organic EL element 500d according to the present embodiment is not limited to the configuration illustrated in FIG. 11.

As described above, in the present embodiment, since the organic EL element 500d includes at least one organic layer containing the high glass transition temperature material having a glass transition point of 120° C. or higher, it is possible to avoid changes in the conductive characteristics of the organic EL element 500d even though the display panel 100 is locally heated by the vibration source such as the vibration excitation unit 308 or the heat source 300. Therefore, in the present embodiment, since there are no differences in the characteristics of the organic EL elements 500d in the entire display panel 100, the occurrence of color unevenness of the displayed images on the display panel 100 can be minimized.

### 7. FIFTH EMBODIMENT

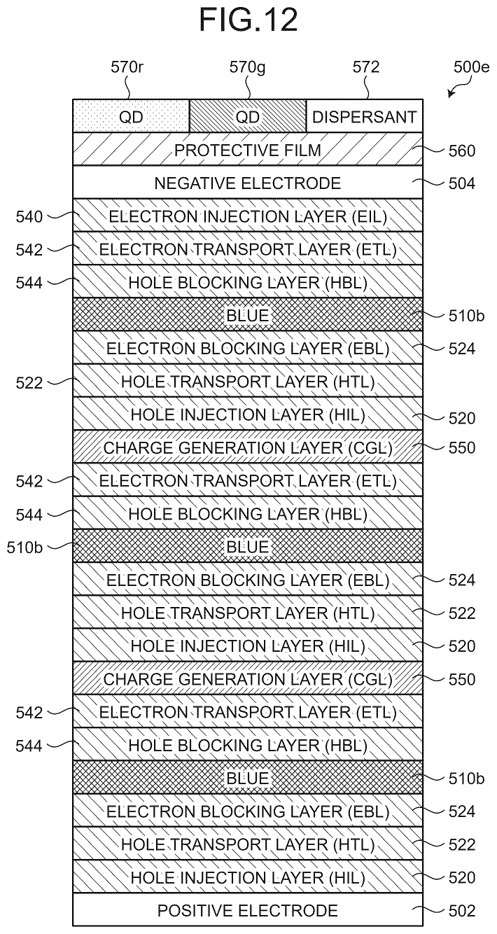

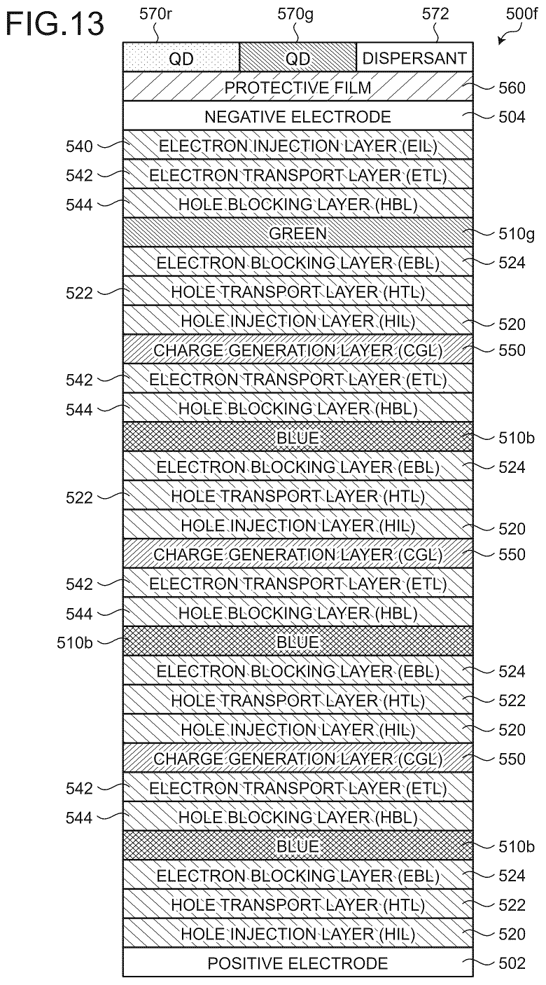

Next, a configuration example of an organic EL element 500e according to a fifth embodiment of the present disclosure will be described with reference to FIGS. 12 and 13. FIGS. 12 and 13 are diagrams illustrating a configuration example of the organic EL element 500e of the present embodiment. In the present embodiment, the organic EL element 500e in which quantum dots are applied to a tandem structure of the organic EL elements 500c according to the third embodiment described above will be described.

As illustrated in FIG. 12, in the organic EL element 500e according to the present embodiment, three laminated structures are stacked, each including a hole transport layer 522, an electron blocking layer 524, an emissive layer 510, a hole blocking layer 544, and an electron transport layer 542, which are sequentially layered. Furthermore, in the present embodiment, the three laminated structures are sandwiched between a positive electrode 502 and a hole injection layer 520, and an electron injection layer 540 and a negative electrode 504, and charge generation layers 550 are provided between the laminated structures in the same manner as in the second embodiment.

Furthermore, in the present embodiment, the emissive layers 510 of all the laminated structures are emissive layers 510b that emit blue light. Note that, in the present embodiment, in a case where three or more laminated structures are stacked, some of a plurality of emissive layers 510 may emit light other than blue light.

Note that, in the present embodiment, the number of laminated structures is not limited to three, and is not particularly limited as long as two or more laminated structures are stacked. In addition, in the present embodiment, it is sufficient that at least one layer of a plurality of layers in the laminated structures constituting the organic EL element 500e contains a diamondoid compound. Furthermore, in the present embodiment, it is preferable that at least one layer of the plurality of layers in the laminated structures constituting the organic EL element 500e contains an adamantane compound.

Furthermore, in the present embodiment, a protective film 560 is formed on the negative electrode 504, and quantum dot layers 570r and 570g and a dispersant 572 are provided on the protective film 560 in the same manner as in the fourth embodiment.

In addition, in the present embodiment, as illustrated in FIG. 13, in an organic EL element 500f, four laminated structures are stacked, each including a hole transport layer 522, an electron blocking layer 524, an emissive layer 510, a hole blocking layer 544, and an electron transport layer 542, which are sequentially layered. Furthermore, in FIG. 13, among the emissive layers 510 in the laminated structures, three emissive layers 510 from the lower side may be emissive layers 510b that emit blue light, and one emissive layer 510 from the upper side may be an emissive layer 510g that emits green light.

Note that, in the present embodiment, each layer denoted by the same reference numeral as those of the first to fourth embodiments can have the same function as that of each layer in the first to fourth embodiments and can be formed of the same material, and thus the description of details of the same layer will not be repeated here.

Note that the configuration of the organic EL element 500e according to the present embodiment is not limited to the configurations illustrated in FIGS. 12 and 13.

As described above, in the present embodiment, since the organic EL element 500e includes at least one organic layer containing the high glass transition temperature material having a glass transition point of 120° C. or higher, it is possible to avoid changes in the conductive characteristics of the organic EL element 500e even though the display panel 100 is locally heated by the vibration source such as the vibration excitation unit 308 or the heat source 300. Therefore, in the present embodiment, since there are no differences in the characteristics of the organic EL elements 500e in the entire display panel 100, the occurrence of color unevenness of the displayed images on the display panel 100 can be minimized.

### 8. SIXTH EMBODIMENT

In the organic EL element 500 according to the embodiments of the present disclosure described above, a method of forming each layer is not particularly limited. For example, for the organic EL element 500 according to the embodiments of the present disclosure, a known vacuum vapor deposition method, spin coating method, or the like can be used for the formation. For example, each layer such as the emissive layer 510 can be formed by a known method such as a vacuum vapor deposition method, a molecular beam epitaxy method (MBE), or a coating method such as a dipping method, a spin coating method, a casting method, a bar coating method, or a roll coating method, using a solution dissolved in a solvent.

In addition, in the embodiments of the present disclosure, for example, as a method of forming the electron transport layer 542 and the like, a method of simultaneously depositing (co-depositing) two compounds from different deposition sources may be adopted, or a method of previously mixing these compounds and then depositing from the same deposition source may be adopted.

In addition, the negative electrode 504 and the like are usually formed by a vacuum vapor deposition method or a sputtering method. In addition, in a case where a silver paste or the like is used as the negative electrode 504, a coating method, an inkjet method, or the like can be used.

### 9. CONCLUSION

As described above, in each embodiment of the present disclosure, since the organic EL element 500 includes the organic layer containing the high glass transition temperature material having a glass transition point of 120° C. or higher, it is possible to avoid changes in the conductive characteristics of the organic EL element 500 even though the display panel 100 is locally heated by the vibration source such as the vibration excitation unit 308 or the heat source 300. Therefore, in the present embodiment, since there are no differences in the characteristics of the organic EL elements 500 in the entire display panel 100, the occurrence of color unevenness of the displayed images on the display panel 100 can be minimized.

Furthermore, according to the present embodiment, since the characteristics of the organic EL element 500 of the display panel 100 are less likely to be changed by heat, the display panel 100 itself can be made thinner. In addition, according to the present embodiment, since it is not necessary to provide the heat dissipation film 200, the cost of the display 1 can be reduced. Furthermore, since it is not necessary to provide the heat dissipation film 200, in the display (display device) 1 according to the embodiments of the present disclosure, the vibration excitation units, the system circuit, and the like are provided as various drive units that are provided on the back surface side of the display panel to be in contact with the display panel and drive the display panel. Specifically, in the display 1 according to the embodiments of the present disclosure, the vibration excitation units 308 that are in contact with the back surface and vibrate the display panel, and the display control unit 302 that controls display on the display panel 100 are provided on the back surface side of the display panel 100 having the plurality of organic EL elements. Furthermore, the main control unit 304 that controls the vibration excitation units 308 and the display control unit 302, and the power supply unit 306 that supplies power to the display panel 100, the vibration excitation units 308, the display control unit 302, the main control unit 304, and the like are provided on the back surface side of the above-described display panel 100 to be in contact with the back surface.

In addition, according to the present embodiment, since the occurrence of color unevenness of the displayed images on the display panel 100 can be minimized even though a larger number of the vibration excitation units 308 or the vibration excitation units 308 with a larger output are attached to the display panel 100, it is possible to achieve audio amplification while maintaining high quality images.

Furthermore, in the present embodiment, by using the diamondoid compound as the high glass transition temperature material having a glass transition point of 120° C. or higher, the display 1 can be manufactured without significantly changing manufacturing processes. That is, according to the present embodiment, the display 1 can be easily manufactured.

Note that the technology according to the present disclosure may be applied to a display device that functions as a display unit for various electronic devices. Specifically, the technology according to the present disclosure can be applied to a display device of an electronic device such as a television device, a tablet, or a smartphone.

### 10. ENDNOTES

Although the suitable embodiments of the present disclosure have been described in detail with reference to the accompanying drawings, the technical scope of the present disclosure is not limited to such examples. It is obvious that a person having ordinary knowledge in the technical field of the present disclosure can conceive various changes or modifications within the scope of the technical idea described in the claims, and it is understood that these also naturally fall within the technical scope of the present disclosure.

In addition, the effects described in the present specification are merely illustrative or exemplary, and are not restrictive. That is, the technology according to the present disclosure can exhibit other effects obvious to those skilled in the art from the description of the present specification together with or instead of the above effects.

Note that the present technology can also have the following configurations.

(1) A display device comprising:
a display panel that has a plurality of organic EL elements; and
a drive unit that is provided to be in contact with the display panel and drives the display panel, wherein
each organic EL element includes an organic layer that contains a high glass transition temperature material having a glass transition point of 120° C. or higher.

(2) The display device according to (1), wherein
the organic layer contains a diamondoid compound as the high glass transition temperature material.

(3) The display device according to (2), wherein
the organic layer contains an adamantane compound as the high glass transition temperature material.

(4) The display device according to (2), wherein
the display device is provided with, as the drive unit, a vibration excitation unit that vibrates the display panel.

(5) The display device according to (4), wherein
the display device is provided with, as the drive unit, at least one selected from the group consisting of:
a display control unit that controls display on the display panel;
a main control unit that controls the vibration excitation unit or the display control unit; and
a power supply unit that supplies power to the display panel, the vibration excitation unit, the display control unit, or the main control unit.

(6) The display device according to (4) or (5), wherein
the organic layer contains one diamondoid compound selected from the group consisting of a plurality of diamondoid compounds containing units represented by Formulae (1) to (6), respectively,

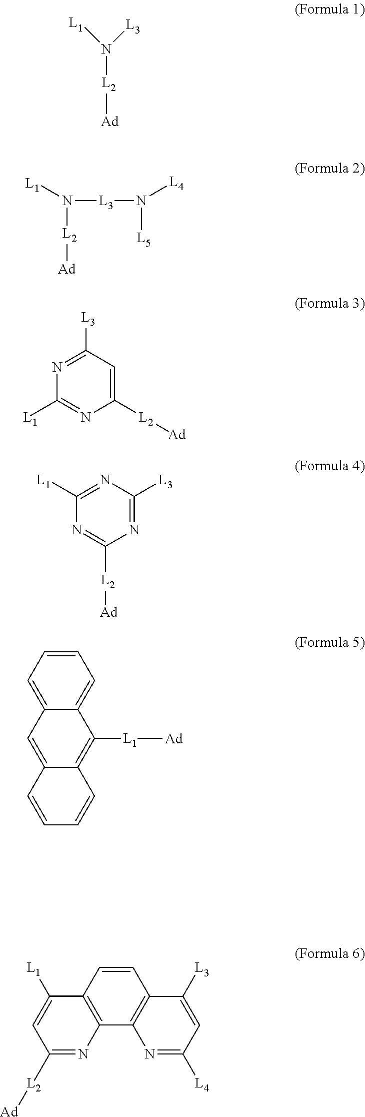

wherein, L₁ to L₅ each independently represent a single bond or a linker, and
Ad is a monovalent functional group containing one or more substituted or unsubstituted diamondoids.

(7) The display device according to any one of (4) to (6), wherein
each organic EL element has a laminated structure in which
an emissive layer,
a first electrode and a second electrode with the emissive layer sandwiched between the first electrode and the second electrode,
a hole injection layer that is provided between the emissive layer and the first electrode, and
an electron injection layer provided between the emissive layer and the second electrode
are layered, and
at least one layer selected from the group consisting of the emissive layer, the hole injection layer, and the electron injection layer contains the diamondoid compound.

(8) The display device according to (7), wherein
the hole injection layer contains the diamondoid compound containing a unit represented by Formula (7) or Formula (8),

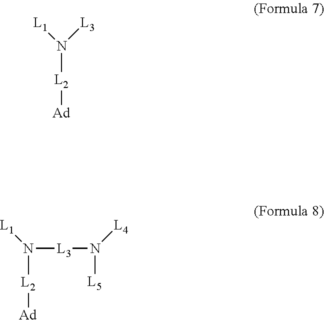

wherein, L₁ to L₅ each independently represent a single bond or a linker, and
Ad is a monovalent functional group containing one or more substituted or unsubstituted diamondoids.

(9) The display device according to (7) or (8), wherein
the emissive layer contains the diamondoid compound containing a unit represented by Formula (9),

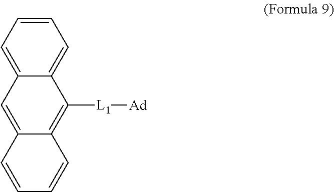

wherein, L₁ represents a single bond or a linker, and
Ad is a monovalent functional group containing one or more substituted or unsubstituted diamondoids.

(10) The display device according to any one of (7) to (9), wherein the emissive layer emits any one of blue light, red light, green light, yellow light, or cyan light.

(11) The display device according to (10), wherein, in the laminated structure, two or more emissive layers that emit light of different colors are layered.

(12) The display device according to any one of (7) to (11), wherein
the laminated structure includes
a hole transport layer between the hole injection layer and the emissive layer, and
the hole transport layer contains the diamondoid compound containing a unit represented by Formula (10) or

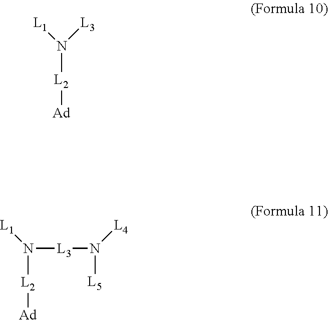

wherein, L₁ to L₅ each independently represent a single bond or a linker, and
Ad is a monovalent functional group containing one or more substituted or unsubstituted diamondoids.

(13) The display device according to (12), wherein
the laminated structure includes
an electron blocking layer between the hole transport layer and the emissive layer, and
the electron blocking layer contains the diamondoid compound containing a unit represented by Formula (12),

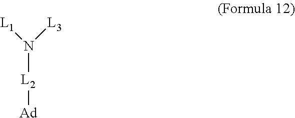

wherein, L₁ to L₃ each independently represent a single bond or a linker, and
Ad is a monovalent functional group containing one or more substituted or unsubstituted diamondoids.

(14) The display device according to any one of (7) to (13), wherein
the laminated structure includes
an electron transport layer between the electron injection layer and the emissive layer, and
the electron transport layer contains one diamondoid compound selected from the group consisting of a plurality of diamondoid compounds containing units represented by Formulae (13) to (15), respectively,

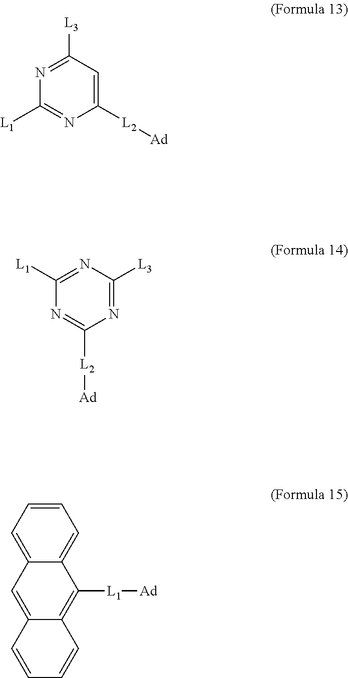

wherein, L₁ to L₃ each independently represent a single bond or a linker, and
Ad is a monovalent functional group containing one or more substituted or unsubstituted diamondoids.

(15) The display device according to (14), wherein
the laminated structure includes
a hole blocking layer between the electron transport layer and the emissive layer, and
the hole blocking layer contains the diamondoid compound containing a unit represented by Formula (16) or Formula (17),

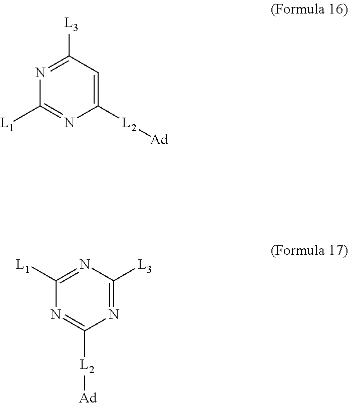

wherein, L₁ to L₃ each independently represent a single bond or a linker, and
Ad is a monovalent functional group containing one or more substituted or unsubstituted diamondoids.

(16) The display device according to (14) or (15), wherein
the organic EL element includes two or more laminated structures stacked,
a charge generation layer is provided between the laminated structures, and
the charge generation layer contains the diamondoid compound containing a unit represented by Formula (18),

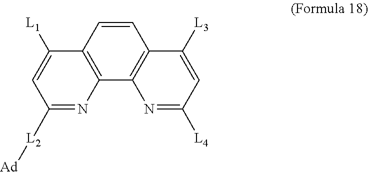

wherein, L₁ to L₄ each independently represent a single bond or a linker, and
Ad is a monovalent functional group containing one or more substituted or unsubstituted diamondoids.

(17) The display device according to (16), wherein the two or more laminated structures stacked have emissive layers that emit light of different colors.

(18) The display device according to any one of (7) to (10), wherein
the organic EL element includes a quantum dot layer provided on the laminated structures.

(19) The display device according to (18), wherein the quantum dot layer contains the diamondoid compound.

(20) An electronic device comprising a display device, wherein
the display device includes
a display panel that has a plurality of organic EL elements, and
a drive unit that is provided to be in contact with the display panel and drives the display panel, and
each organic EL element includes an organic layer that contains a high glass transition temperature material having a glass transition point of 120° C. or higher.

### REFERENCE SIGNS LIST

1 DISPLAY
1A DISPLAY REGION
1B FRAME REGION
10, 100 DISPLAY PANEL
11 PIXEL
11A PIXEL CIRCUIT
11B, 500, 500A, 500C, 500D, 500E, 500F ORGANIC EL ELEMENT
13 PANEL
14, 200 HEAT DISSIPATION FILM
20 FRAME
30 PRINTED CIRCUIT
40 SYSTEM CIRCUIT BOARD
41 RECEPTION CIRCUIT
42 PROCESSOR
43 MEMORY
43A TABLE
44 DECODER
45 IMAGE SIGNAL PROCESSING CIRCUIT
46 GRAPHICS GENERATION CIRCUIT
47 OLED PANEL DRIVE CIRCUIT
48 AUDIO SIGNAL PROCESSING CIRCUIT
49 VIBRATION EXCITATION UNIT DRIVE CIRCUIT
51 DETECTION SIGNAL PROCESSING CIRCUIT
300 HEAT SOURCE (VIBRATION SOURCE)
302 DISPLAY CONTROL UNIT
304 MAIN CONTROL UNIT
306 POWER SUPPLY UNIT
308 VIBRATION EXCITATION UNIT
502 POSITIVE ELECTRODE
504 NEGATIVE ELECTRODE
510, 510B, 510G, 510R EMISSIVE LAYER
520 HOLE INJECTION LAYER
522 HOLE TRANSPORT LAYER
524 ELECTRON BLOCKING LAYER
540 ELECTRON INJECTION LAYER
542 ELECTRON TRANSPORT LAYER
544 HOLE BLOCKING LAYER
550 CHARGE GENERATION LAYER
560 PROTECTIVE FILM
570, 570G, 570R QUANTUM DOT LAYER
572 DISPERSANT

1. A display device comprising:
a display panel that has a plurality of organic EL elements; and
a drive unit that is provided to be in contact with the display panel and drives the display panel, wherein
each organic EL element includes an organic layer that contains a high glass transition temperature material having a glass transition point of 120° C. or higher.

2. The display device according to claim 1, wherein
the organic layer contains a diamondoid compound as the high glass transition temperature material.

3. The display device according to claim 2, wherein
the organic layer contains an adamantane compound as the high glass transition temperature material.

4. The display device according to claim 2, wherein
the display device is provided with, as the drive unit, a vibration excitation unit that vibrates the display panel.

5. The display device according to claim 4, wherein
the display device is provided with, as the drive unit, at least one selected from the group consisting of:
a display control unit that controls display on the display panel;
a main control unit that controls the vibration excitation unit or the display control unit; and
a power supply unit that supplies power to the display panel, the vibration excitation unit, the display control unit, or the main control unit.

6. The display device according to claim 4, wherein
the organic layer contains one diamondoid compound selected from the group consisting of a plurality of diamondoid compounds containing units represented by Formulae (1) to (6), respectively, 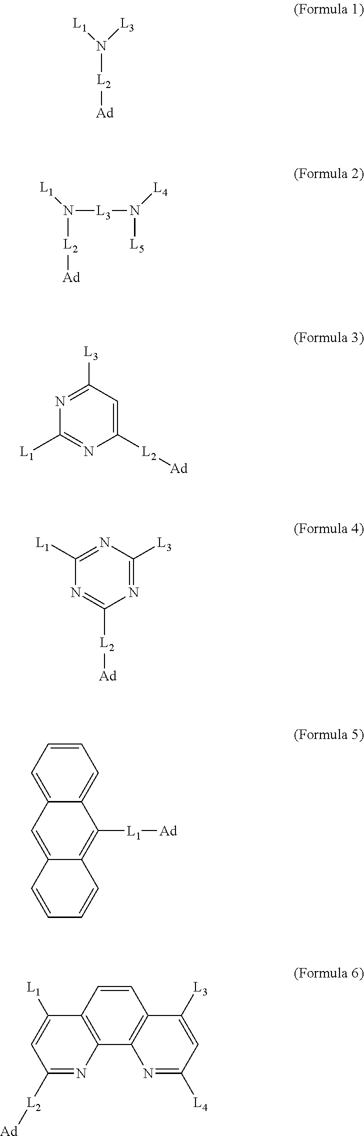
wherein, L₁ to L₅ each independently represent a single bond or a linker, and
Ad is a monovalent functional group containing one or more substituted or unsubstituted diamondoids.

7. The display device according to claim 4, wherein
each organic EL element has a laminated structure in which
an emissive layer,
a first electrode and a second electrode with the emissive layer sandwiched between the first electrode and the second electrode,
a hole injection layer that is provided between the emissive layer and the first electrode, and
an electron injection layer provided between the emissive layer and the second electrode
are layered, and
at least one layer selected from the group consisting of the emissive layer, the hole injection layer, and the electron injection layer contains the diamondoid compound.

8. The display device according to claim 7, wherein
the hole injection layer contains the diamondoid compound containing a unit represented by Formula (7) or Formula (8), 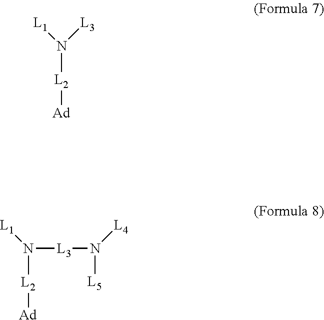
wherein, L₁ to L₅ each independently represent a single bond or a linker, and
Ad is a monovalent functional group containing one or more substituted or unsubstituted diamondoids.

9. The display device according to claim 7, wherein
the emissive layer contains the diamondoid compound containing a unit represented by Formula (9), 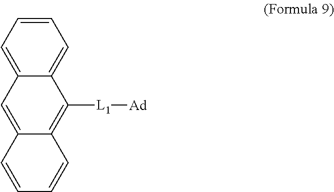
wherein, L₁ represents a single bond or a linker, and
Ad is a monovalent functional group containing one or more substituted or unsubstituted diamondoids.

10. The display device according to claim 7, wherein the emissive layer emits any one of blue light, red light, green light, yellow light, or cyan light.

11. The display device according to claim 10, wherein, in the laminated structure, two or more emissive layers that emit light of different colors are layered.

12. The display device according to claim 7, wherein
the laminated structure includes
a hole transport layer between the hole injection layer and the emissive layer, and
the hole transport layer contains the diamondoid compound containing a unit represented by Formula (10) or Formula (11), 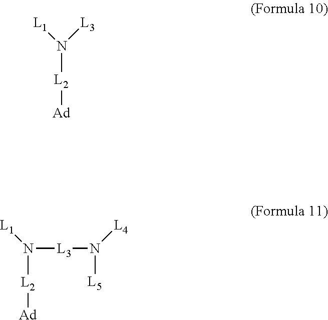
wherein, L₁ to L₅ each independently represent a single bond or a linker, and
Ad is a monovalent functional group containing one or more substituted or unsubstituted diamondoids.

13. The display device according to claim 12, wherein
the laminated structure includes
an electron blocking layer between the hole transport layer and the emissive layer, and
the electron blocking layer contains the diamondoid compound containing a unit represented by Formula (12), 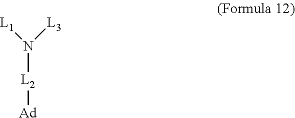
wherein, L₁ to L₃ each independently represent a single bond or a linker, and
Ad is a monovalent functional group containing one or more substituted or unsubstituted diamondoids.

14. The display device according to claim 7, wherein
the laminated structure includes
an electron transport layer between the electron injection layer and the emissive layer, and
the electron transport layer contains one diamondoid compound selected from the group consisting of a plurality of diamondoid compounds containing units represented by Formulae (13) to (15), respectively, 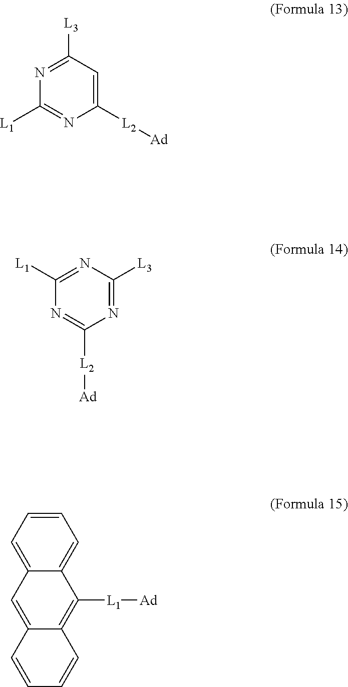
wherein, L₁ to L₃ each independently represent a single bond or a linker, and
Ad is a monovalent functional group containing one or more substituted or unsubstituted diamondoids.

15. The display device according to claim 14, wherein
the laminated structure includes
a hole blocking layer between the electron transport layer and the emissive layer, and
the hole blocking layer contains the diamondoid compound containing a unit represented by Formula (16) or Formula (17), 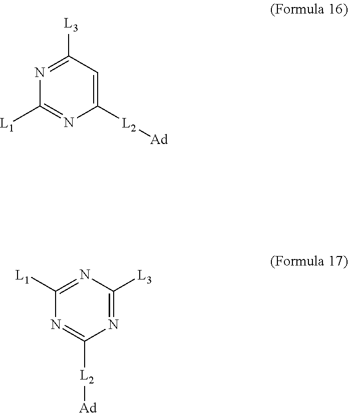
wherein, L₁ to L₃ each independently represent a single bond or a linker, and
Ad is a monovalent functional group containing one or more substituted or unsubstituted diamondoids.

16. The display device according to claim 14, wherein
the organic EL element includes two or more laminated structures stacked,
a charge generation layer is provided between the laminated structures, and
the charge generation layer contains the diamondoid compound containing a unit represented by Formula (18), 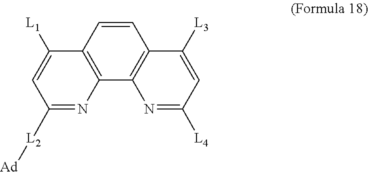
wherein, L₁ to L₄ each independently represent a single bond or a linker, and
Ad is a monovalent functional group containing one or more substituted or unsubstituted diamondoids.

17. The display device according to claim 16, wherein the two or more laminated structures stacked have emissive layers that emit light of different colors.

18. The display device according to claim 7, wherein
the organic EL element includes a quantum dot layer provided on the laminated structures.

19. The display device according to claim 18, wherein the quantum dot layer contains the diamondoid compound.

20. An electronic device comprising a display device, wherein
the display device includes
a display panel that has a plurality of organic EL elements, and
a drive unit that is provided to be in contact with the display panel and drives the display panel, and
each organic EL element includes an organic layer that contains a high glass transition temperature material having a glass transition point of 120° C. or higher.
